(19) United States
(12) Patent Application Publication
(10) Pub. No.: US 2025/0070534 A1
(43) Pub. Date: Feb. 27, 2025

(54) METHOD FOR MONITORING AN OPTICAL SIGNAL EXTRACTED FROM AN OPTICAL CAVITY

(71) Applicant: Institute of Science and Technology - Austria, Klosterneuburg (AT)

(72) Inventors: Fritz DIORICO, Wien (AT); Onur HOSTEN, Wien (AT)

(73) Assignee: Institute of Science and Technology - Austria, Klosterneuburg (AT)

(21) Appl. No.: 18/723,604

(22) PCT Filed: Dec. 21, 2022
(86) PCT No.: PCT/EP2022/087250

§ 371 Date: Jun. 24, 2024

(30) Foreign Application Priority Data
Dec. 22, 2021 (EP) 21216871.0
Sep. 9, 2022 (EP) 22194904.3

(51) Int. Cl. H01S 5/0683; G01J 1/42; H01S 5/06

(52) U.S. Cl. CPC H01S 5/0683; G01J 1/4257; H01S 5/0607

(57) ABSTRACT

A method for monitoring an optical signal (15) extracted from an optical cavity (42), such as a laser cavity (22), comprising the steps:
receiving at least a portion of the optical signal (15) as an incident signal (1);
converting the incident signal (1) into an error signal (9) by applying a conversion configuration including:
   propagating the incident signal (1) onto a detector (2) and
   deriving the error signal (9) based on a geometric beam shape, in particular based on a beam shape ellipticity, for example as proportional to a beam shape ellipticity, of the propagated incident signal (1) on the detector (2);
wherein the error signal (9) has a local minimum, in particular a global minimum (13), and a local maximum, in particular a global maximum (14),
wherein the local minimum and the local maximum delimit an interval (59) of error signal (9) values,
wherein the conversion configuration configures the interval (59) to comprise a zero-crossing (58) of the error signal (9) when the optical cavity (42) is in a target state.

Optical cavities are among the key components in modern science and engineering and enable a vast number of applications. Optical cavities can be found for example in lasers as well as in a broad variety of measurement instruments, such as microscopes or in spectroscopy. Applications range for example from the detection of gravitational waves over laser welding to face recognition techniques, to name just a few. In order to ensure a desired behaviour of an optical cavity, e.g., an optical cavity of a laser, properties of the optical cavity should be monitored. Also, for controlling a laser, it is necessary to measure and quantify the output of the laser and to derive an estimator for the deviation of an actual state of the laser relative to a nominal or reference state.

For example, laser frequency stabilization-which can be achieved by stabilizing and/or controlling a lasers' optical cavity-is indispensable in atomic time keeping, gravitational wave detection, tests of relativity, atom interferometry, and in the quantum control of various systems such as atoms, nanoparticles and mechanical oscillators. As an example, contemporary atomic clocks require milliHertz-linewidth lasers to probe long-lived optical atomic transitions, and the level of precision in stabilization of laser frequencies to reference optical cavities play a crucial role in reaching the state-of-the-art performance levels.

Another aspect where it is crucial to quantify a deviation from a target state of an optical cavity to a reference state is the locking of a laser to the optical cavity. In this case, the deviation from the reference state may be relative to a state of the laser, which is to be locked to the optical cavity.

A number of methods have been developed over the decades to address the task of finding a suitable measurement of a state of an optical cavity and a suitable estimator to quantify a deviation from a reference state. For example, the estimator may indicate a detuning of a laser with respect to an optical cavity. These methods are for example utilized by: side-of-fringe intensity methods, polarization-based methods, frequency modulation techniques similar to Pound-Drever-Hall (PDH), and lastly, spatial mode interference methods such as tilt locking.

In Diorico, F., et al.: “Laser-cavity locking at the 10\hat{ }(−7) instability scale utilizing beam ellipticity.” arXiv preprint arXiv: 2203.04550 (2022) a method for locking a laser to an optical cavity is presented. A laser beam is directed at an optical cavity. The laser frequency is in resonance (or near resonance) with the cavity. A reflected beam is focused on a quadrupole photodiode with a lens. The method relies on the interference of the fundamental TEM₀₀ mode of an optical cavity with second order spatial modes, leading to an elliptic beam on the detector. Based on the ellipticity, an error signal is derived, which is used as a feedback for the laser to achieve stable laser cavity locking. The method is referred to as “squash locking”. The publication mentions that a generic squash locking method may be applicable to stabilize laser injection locking. However, the publication does not give a hint how to apply the disclosed method in different contexts.

In Ottaway, D. J., et al. “Stabilization of injection-locked lasers using spatial mode interference.” IEEE journal of quantum electronics 37.5 (2001): 653-657 a method to stabilize the injection locking of a laser by using tilt locking to generate an error signal is disclosed. The technique relies on the interference of the TEM₀₀ mode with a first order spatial mode of the laser output, which is measured by a quadrant photodiode. The quadrant photodiode has the two quarters of the top and bottom halves added together. Therefore, the quadrant photodiode has effectively two active areas each consisting of added sensor regions. At zero frequency difference (in resonance), the two outputs of the photodiode are equal in amplitude but have opposite phases. These two outputs are subtracted, giving a zero resultant output. At nonzero frequency difference, the TEM₀₀ field interferes more constructively with one of the TEM₀₁ lobes and more destructively with the other. Thus, the signal depends on a shift of the beam or the intensity on the detector as well as on the alignment of the detector relative to the beam. The error signal, however, includes no information on the beam shape.

For example, in case the beam shape would change from circular to elliptic, the two outputs would still be equal as long as the ellipse is centred—regardless of the rotation of the elliptical beam on the detector. In addition, the incident laser beam needs to be misaligned with respect to the optical axis of the cavity of the slave laser. In summary, the error signal is sensitive to misalignment of the optical components, in particular the detector. The signal is fed-back to a piezo-electric transducer so as to stabilize the injection-locking by controlling the injection of the master signal.

Further details on the tilt locking technique are disclosed in Shaddock, D. A., M. B. Gray, and D. E. McClelland. “Frequency locking a laser to an optical cavity by use of spatial mode interference.” Optics letters 24.21 (1999): 1499-1501.

Known methods to monitor and quantify a state of an optical cavity rely on complex mechanisms and are sensitive to drifts, in particular to alignment drifts.

It is therefore an object of the invention to provide a method for measuring and quantifying an optical signal extracted from an optical cavity and to derive an estimator for the deviation of an actual state of the optical cavity relative to a nominal or reference state, which achieves a reduced complexity, is purely passive, in particular is in-sensitive to alignment drifts, and/or comprises a more robust implementation.

This is achieved by a method for monitoring an optical signal extracted from an optical cavity, such as a laser cavity, comprising the steps:
receiving at least a portion of the optical signal as an incident signal;
converting the incident signal into an error signal by applying a conversion configuration including:
   propagating the incident signal onto a detector and
   deriving the error signal based on a geometric beam shape, in particular based on a beam shape ellipticity, for example as proportional to a beam shape ellipticity, of the propagated incident signal on the detector;
wherein the error signal has a local minimum, in particular a global minimum, and a local maximum, in particular a global maximum,
wherein the local minimum and the local maximum delimit an interval of error signal values,
wherein the conversion configuration configures the interval to comprise a zero-crossing of the error signal when the optical cavity is in a target state.

The optical cavity may, for example, be a linear cavity or a ring cavity. The optical cavity may for example be a two-mirror cavity or a three-mirror cavity. However, a cavity with any number of mirrors and any geometry may be used. The optical cavity may be a free-space cavity or a non-free-space cavity, such as a micro-chip-based optical cavity. E.g., the optical cavity may be a whispering gallery mode resonator, where the light circulates around the perimeter (inside the material) of a sphere or a toroid. The optical cavity could also be a fiber ring, into which light could be coupled evanescently.

An optical signal extracted from the optical cavity may for example be light leaking out of the optical cavity. For example, the optical cavity may be the cavity, i.e., the optical resonator, of a laser. In this case, the optical signal may be the output signal of the laser. The optical signal extracted from the optical cavity may comprise an optical signal, which is reflected by the optical cavity. For example, if a laser is locked to the optical cavity, the laser may emit light onto or into the optical cavity. A part of the laser's light may be reflected by the cavity. Optionally, the optical signal may comprise both signal leaking out of the optical cavity and signal reflected by the optical cavity.

The output signal may for example be split by means of a beam splitter to receive a portion of the optical signal extracted from the optical cavity as an incident signal. Optionally, the total output signal may be used as the incident signal.

Consequently, a conversion configuration is applied to the incident signal. The conversion configuration includes propagating the incident signal onto a detector and deriving an error signal based on a geometrical beam shape of the propagated incident signal. The conversion configuration therefore includes manipulation of the incident beam, e.g., by means of optical components, the detection and quantification of the incident signal as well es the derivation of the error signal. The error signal is an estimator for a deviation of the actual state of the optical cavity, e.g., the optical cavity of a laser, to a reference state. The conversion configuration uses the incident signal as an input and outputs the error signal based on the incident signal.

To understand how the error signal is generated, the Hermite-Gaussian (HG) spatial modes supported by optical cavities such as a laser cavity should be recalled. These are a set of Transverse Electromagnetic Modes (TEMₘₙ), that a cavity, e.g., the cavity of a laser, can support. The subscripts m and n are positive integers for each orthogonal axes in the transverse direction of beam propagation. The sum m+n is called the mode order which can either be odd or even. Starting from a perfectly aligned optical mode coming into an optical cavity, odd modes are induced by misaligning am input beam either by tilting or shifting the input beam. Even modes on the other hand are induced by focusing/mode mismatch and are independent of tilting or shifting of the input beam.

Earlier spatial mode interference implementations such as tilt locking rely on inducing 1^{st} order (TEM₀₁ and TEM₁₀) modes by tilting/misaligning an input beam, which is incident on the optical cavity. Here, of interest are the fundamental HG modes TEM₀₀ labelled ‘00’, and specific second-order HG modes, 2^{nd} order TEM₁₁-like modes, that we label ‘+’, which are both even modes. Even modes are induced by mode mismatch and make the presented method insensitive to misalignment drifts that generate 1st order odd modes. For example, a slightly elliptical beam with a horizontal/vertical orientation can mathematically be decomposed into a main ‘00’ component and a small ‘+’ component. For such a (laser) beam, the phase difference between these two modes encodes the information about ellipticity. Near a ‘00’ resonance, the two modes acquire a differential phase shift, since only one of them resonate given that different order modes are generically non-degenerate. By way of this mechanism, the output signal of the optical cavity can acquire different geometric beam shapes, in particular opposite ellipticities, on opposite sides of the resonance of the optical cavity. To harness this effect, the geometric beam shape, in particular the beam shape ellipticity or beam mode shape ellipticity, of the output signal of the optical cavity, e.g., the optical cavity of a laser, may be measured. In general, a sensor sensitive to 2^{nd} order spatial modes of the output signal of the optical cavity can be used to monitor an optical signal extracted from the optical cavity. In principle, this works for any beam polarization and irrespective of the actual beam polarization.

These modes generically possess different resonance frequencies. In terms of the cavity modes, the spatial decomposition of a slightly elliptical beam that is diagonally oriented is given mostly by the TEM₀₀ mode with a small contribution of the ‘TEM₁₁’ 2nd order mode. For such a beam, the phase difference between these two modes encodes the information about the departure from circularity. This results in a shape change in the output signal. By way of this mechanism, the output signal can be made to acquire opposite ellipticities on opposite sides of the resonance, thus, generating a determinable error signal. To harness this feature, an error signal proportional to the beam shape ellipticity or beam mode shape ellipticity of the output signal may be used.

In general, deriving the error signal based on the geometric beam shape of the incident signal means that the error signal is a function, wherein at least one parameter of the function is a parameter characterizing the geometric beam shape of the incident beam. In particular, the error signal may be directly proportional to a geometric beam ellipticity. The beam ellipticity may be defined according to ISO 11145:2018. Alternatively, the eccentricity may be used.

The method is initiated or initially calibrated before the method is used. A setpoint is set by starting with an optical cavity in a target state. The terms “setpoint”, “reference point” and “target state” are used synonymously for the purpose of this disclosure. Relatively to this setpoint, an error signal that indicates a deviation from the setpoint is derived. As explained above, the relative change in beam shape with respect to the beam shape at the setpoint can be used to quantify the deviation from the setpoint.

The error signal has a local minimum, in particular a global minimum, and a local maximum, in particular a global maximum, wherein the local minimum and the local maximum delimit an interval of error signal values. The conversion configuration configures the interval to comprise a zero-crossing of the error signal when the optical cavity is in a target state. The error signal is zero at the setpoint, i.e., when the optical cavity is in the target state. An error signal of zero indicates that there is no deviation of the actual state of the optical cavity from the target state. The error signal can have a sign and a magnitude, the sign can optionally indicate the direction of the deviation of the actual state from the target state, i.e., if an operation parameter of the optical cavity, in particular a laser, should be increased or decreased to reach the target state. The magnitude of the error signal can be an indication of the magnitude of the necessary change of at least one operation parameter in order to reach the setpoint.

For example, at least one operation parameter of the optical cavity is one or more of the following:
temperature of the optical cavity,
path length of the optical cavity.

In general, the path length of the optical cavity is crucial for the mode distribution of the optical cavity. The temperature influences the path length as the path length can increase or decrease depending on the temperature change due to thermal expansion. The temperature can optionally be changed by means of a Peltier element or for example by a separate heating element, such as an electrical heating element, and a separate cooling element, such as, for example, a fan.

A zero-crossing of the error signal lies in an interval between a local minimum and a local maximum of the error signal. Zero-crossing refers to the error signal having a value of zero. A non-zero error signal may indicate a detuning of the optical cavity from the target state. For example, the error signal may have a positive value in case the optical path length within the optical cavity is greater than the optical path length would be in the reference state. Vice versa, the error signal may have a negative value in case the optical path length within the optical cavity is lower than the optical path length would be in the reference state.

Optionally, the local minimum is a global minimum. Optionally, the local maximum is a global maximum. Optionally, there is no further extreme value between the local minimum and the local maximum. The error signal comprises an interval extending from the local minimum to the local maximum. The local minimum and the local maximum therefore delimit an interval of error signal values.

The detector may be a photodiode, for example an avalanche photodiode. The detector may be a phase plate or mode converter or comprise a phase plate or mode converter. The detector may translate the incident signal into an electrical signal. However, the detector is not limited to electric signals. For example, the detector may be configured to generate an optical signal based on the incident signal. In general, the invention is not limited to any particular form of physical signal that the detector generates based on the incident signal.

For example, the detector may be a photodiode array comprising at least three photodiodes and wherein deriving the error signal includes determining the geometric beam shape of the incident signal. By using an array of photodiodes, the geometric beam shape of the incident signal can be estimated. In order to estimate the geometric beam shape, at least three photodiodes need to be used in order to differentiate between first order and second (or higher) order spatial modes. In principle, the more photodiodes are used, the better the signal shape can be approximated. In general, determining the geometric beam shape of the incident signal means that a parameter value of at least one parameter characterizing the geometric beam shape is determined. Preferably, the photodiodes are arranged in a rectangular regular grid. It is beneficial to minimize the distance between the single photodiodes so that the measurement is most sensitive towards changes of the beam shape.

Optionally, the conversion configuration configures the interval to comprise an error signal value that corresponds to a substantially circular image of the propagated incident signal on the detector. Optionally, the error signal is substantially zero for a circular incident signal and/or a circular image of the incident signal on the detector. The substantially circular incident signal may therefore correspond to the optical cavity being in the reference state. The incident signal acquiring opposite ellipticities for opposite deviations from the reference state can be utilized to determine the error signal. The determined error signal can be thought of as an interference between the resonating ‘00’ mode and the second-order ‘+’ mode, which may both leak out of the optical cavity. Optionally, the zero-crossing of the error signal may be an inversion symmetry point of the error signal. An error signal value of substantially zero for a substantially circular incident signal may therefore lead to an error signal, which is simple to interpret, since the sign and the magnitude of the error signal may give an indication of the magnitude and direction of a detuning of the optical cavity with respect to the setpoint. For example, a temperature of the optical cavity and/or a path length of the optical cavity may be detuned, leading to a non-zero error signal. The sign and the magnitude of the error signal may give an indication in what direction and, for example by how much an operation parameter, such as the temperature of the optical cavity, would have to be adjusted in order to reach the setpoint.

Optionally, the detector may be a quadrant photodiode and wherein deriving the error signal includes determining a diagonal signal of the quadrant photodiode, which diagonal signal is made up of the difference of the sums of signals from diagonal sensor regions of the quadrant photodiode. In this way, the beam shape of the incident signal, in particular the beam ellipticity, can be estimated particularly easily. In particular, the quadrant photodiode is a photodiode with four split sensor regions. The gaps between the sensor regions may be optimized to be as small as possible. In particular, the quadrant photodiode (QPD) produces electrical currents proportional to the input light from each of four sensor regions. The signal from each of the sensor regions is labelled A, B, C and D, wherein on the quadrant photodiode, the sensor regions are arranged in the order A, D, B, C (e.g. in clockwise direction). This allows the following operation: SUM=A+B+C+D, LR=(A+C)−(B+D), UD=(A+D)−(C+B), and DIAG=(A+B)−(C+D). The beam ellipticity can be measured using the DIAG operation. A zero DIAG signal indicates the lack of beam ellipticity, meaning the incident signal comprises a circular beam shape. A non-zero DIAG signal indicates the presence of an elliptic beam on the quadrant photodiode. Opposite signs of the DIAG signal refer to opposite ellipticities. The quadrant photodiode may be an InGaAs-based or a silicon-based detector. The signals may be converted into voltages (e.g., using standard analog electronics with operational amplifiers).

Propagating the incident signal may for example include adjusting an incident angle of the incident signal onto the detector. The incident angle has an influence on the beam shape of the incident signal on the detector. E.g., an incident signal with a circular cross section normal to the propagation axis of the incident signal will appear to have an elliptic beam shape on the detector when the incident angle differs from 90°. An incident signal with an elliptical cross section can appear to have a circular beam shape on the detector with a suitable incident angle. If the detector is a QPD, the DIAG signal can be set to zero by means of the imposed angle. The imposed incident angle is set once during calibration by adjusting a tilt angle of the detector relative to the optical axis of the incident signal and remains constant during operation.

Optionally, propagating the incident signal includes shaping the incident signal, in particular with a shaping lens, preferably with at least a lens, in particular at least a cylindrical lens. By shaping the incident signal, an initial error signal in the target state of the optical cavity can be calibrated. The error signal may be set to zero initially. If the detector is a QPD, the DIAG signal can be set to zero by means of shaping of the incident signal. This can be achieved, for example, if the detector is a QPD and the incident signal is shaped so that the image of the incident signal on the detector is circular. This way, the DIAG signal is zero. The DIAG signal can optionally be used as the error signal without further operations. The position and alignment of beam shaping optics for shaping the incident signal, in particular the at least one lens, preferably the at least one shaping lens, in particular the at least one cylindrical lens, is set once during calibration and remains constant during operation. Shaping the incident signal may also be effected by a prism or any other optical beam shaping device.

Optionally, propagating the incident signal includes defining an axial distance between the detection lens and the detector such that a transmission peak of the incident signal matches a zero-crossing of the error signal. The transmission peak refers to the resonance of an external optical signal with the optical cavity, for example an external optical seed signal with an injection-locked laser. In resonance, the reflected signal at the optical cavity comprises a minimum. The axial distance between the detection lens and the detector refers to their distance along the path of incident signal. For the method, the positions of the detector and the detection lens are fixed during calibration and remain constant during operation. Optionally, the axial distance may be tuned over a tuning interval to determine a curve of the error signal and to set the axial distance. The relative change of the geometric beam shape of the incident signal is most pronounced at the resonance of the optical cavity with the external signal, for example an optical seed signal. Therefore, the method is most sensitive at the transmission peak of the incident signal, which is also a transmission peak of the external optical signal. Optionally, the axial distance may be tuned over a tuning interval to determine a curve of the error signal and to set the axial distance.

In another optional embodiment, propagating the incident signal includes defining an axial distance between the optical cavity and the detector such that a transmission peak of the incident signal matches a zero-crossing of the error signal. The transmission peak corresponds to a reflection minimum of a reflected signal at the optical cavity, i.e., the SUM channel of the quadrant photodiode will give a dip (since the SUM channel of the quadrant photodiode in particular measures the reflection curve). The positions of the detector and the optical cavity are fixed during calibration and remain constant during operation. The distance between the laser and the detector influences the Gouy phase between the TEM₀₀ mode and the second order spatial modes. The resulting image on the detector can therefore be tuned by adjusting the location of the detector relative to the optical cavity. There are axial distances at which the error signal is purely dispersive and other axial distances at which the error signal is purely absorptive or any signal shape in between absorptive and dispersive. Preferably the error signal is dispersive.

Optionally deriving the error signal includes applying an offset to the error signal to set the error signal to zero when the optical cavity is in the target state. The error signal is derived the following way: the incident signal on the detector leads to a signal per photodiode of the detector. Depending on the estimator for the shape of the incident signal, these signals are used. For example, if the detector is a QPD, the DIAG operation may be used for estimating the ellipticity of the signal. The error signal may be set to zero initially during calibration. Since for example the DIAG operation might lead to a residual signal even if the incident signal is substantially circular, an additional offset can be applied to set the error signal initially to zero at the setpoint.

In another embodiment an imbalanced detection operation may be utilized. For example, instead of the DIAG operation an imbalanced operated IDIAG can be used: IDIAG=ε₁(A+B)−ε₂(C+D), where ε₁/ε₂≠1 and ε₁ and ε₂ can be set initially so as to set the error signal to zero. This allows the background offset of the diagonal channel to be tuned in order to provide a zero-crossing for the error signal at a desired state (e.g., at the setpoint).

In another embodiment, propagating the incident signal includes focusing the incident signal onto the detector with a detection lens, preferably with a convex spherical lens. Optionally, the incident signal is focused and/or diverged in at least a first plane and preferably focused and/or diverged in a second plane (not parallel to the first plane), in particular at a different point along the incident signal's path than the focusing/diverging in the first plane). Focusing the incident signal refers to focusing the incident signal in at least one plane. The position and alignment of detection lens for focusing the incident signal onto the detector, preferably the convex spherical lens, may be set once during calibration and remain constant during operation.

Optionally adjusting the axial distance of the detection lens and the detector comprises, optionally prior to adjusting the axial distance of the detection lens and the detector along the optical axis of the incident signal such that the transmission peak of the incident signal matches the zero-crossing of the error signal:
adjusting the axial distance such that an in-plane incident signal waist and an out-of-plane incident signal waist of the incident signal match with a beam waist of a resonance cavity mode of the optical cavity (in particular with a cavity mode mean beam waist, which is the average beam waist of its in- and out-of-plane beam waist). Optionally, this is conducted prior to adjusting the axial distance of the detection lens and the detector along the optical axis of the incident signal such that the transmission peak of an optical signal reflected from the optical cavity matches the zero-crossing of the error signal. Optionally, additionally or alternatively, the axial distance is adjusted such that the in-plane beam waist and out-of-plane beam waist of the incident signal reflected from the cavity match (with each other). A baseline offset on the error signal is attributable to an axial displacement of the detector location from the location where the beam assumes a circular profile (disregarding astigmatism). The axial distance can be chosen such that this baseline offset is eliminated. This match of the beam waists can be used as a first approximation before matching the transmission peak and the zero-crossing or can be used itself. If there is no astigmatism, these two will give the same result. In this case there is no residual astigmatism in the modes, so zeroing the baseline automatically puts one in at the plateau of the transmission. It is also preferable in the context of the method and the device for frequency locking the laser, if the axial distance of the detector and the detection lens is such that an in-plane beam waist and an out-of-plane beam waist of the incident signal reflected from the cavity match with a beam waist of a resonance cavity mode of the optical cavity or are within ±5% or within ±2% or within ±1% of the beam waist of the resonance cavity mode of the optical cavity.

Optionally, the method further comprises the step:
centering the incident signal on the quadrant photodiode by translating the detection lens and/or the quadrant photodiode in the directions perpendicular to the optical axis of the incident signal such that a left-right signal and/or an up-down signal of the quadrant photodiode are minimized, which left-right signal and up-down signal are each made up of the difference of the sums of adjacent sensor regions of the quadrant photodiode, wherein the left-right signal and the up-down signal use the sums of different halves of adjacent sensor regions. Optionally, this is performed iteratively and repeatedly. In this way, the incident signal can be aligned perfectly at the quadrant photodiode, such that the best beam fit over the quadrant photodiode active area is achieved and producing the most accurate error signal.

Optionally, the translation occurs in two directions, which are perpendicular to one another and to the optical axis of the incident signal.

Optionally, the step of adjusting an axial distance of the detection lens and the quadrant photodiode along the optical axis of the incident signal such that the transmission peak of the incident signal matches the zero-crossing of the error signal and the step of centering the incident signal on the quadrant photodiode are conducted iteratively. For every adjustment in the axial distance, the left-right and the up-down signals can to be minimized. By repeating this process, the zero-crossing can be optimized to match exactly the transmission plateau.

The invention further concerns a method for frequency locking a laser to the optical cavity with the method according to the invention, further comprising the steps:
providing a laser beam from the laser;
shaping the laser beam such that the laser beam acquires ellipticity;
directing the laser beam at the optical cavity wherein the laser beam reflected from the optical cavity is the incident signal propagated onto the detector;
locking the laser to the optical cavity based on the error signal.

The method can be used with a laser beam wavelength in a wide range. E.g., the wavelength may be in the ultraviolet range, between 190 nm and 400 nm, the visible range, between 400 nm and 800 nm, in the near-infrared range, between 800 nm and 1800 nm, and/or in the infrared range, between 1800 to at least 3500 nm. Optionally, the error signal is directly proportional to the beam ellipticity of the focused incident signal, in this case the reflected laser beam. Optionally, the error signal is substantially zero for a circular laser beam. Optionally, the laser is locked to the optical cavity based on the error signal by feeding the error signal back to the laser current. The locking is based on monitoring the change in the ellipticity of the laser beam reflected from the optical cavity. The locking may be effected by a closed-loop control.

Under shaping the laser beam such that the laser beam acquires ellipticity is understood that the laser beam is manipulated such that subsequently the laser beam's cross-section differs from a circular cross section at at-least one point, in particular that the laser beam has differing beam waists in two transverse directions at at-least one point. Optionally, the laser beam is focused and/or diverged in at least a first plane and preferably focused and/or diverged in a second plane (not parallel to the first plane), in particular at a different point along the laser beam's path than the focusing/diverging in the first plane).

Shaping the laser beam such that the laser beam acquires ellipticity may optionally be effected by a pair of cylindrical lenses, which have focusing axes oriented non-parallelly, in particular perpendicularly, to each other and/or shaping the laser beam such that the laser beam acquires ellipticity is effected by a combination of lenses, wedged prisms, and/or anamorphic prism pairs, wherein an elliptical or astigmatic beam is created.

Optionally, the two cylindrical lenses have identical focal lengths, further optionally with one oriented horizontally and the other vertically. The focal length is optionally chosen such that if the two lenses were co-located (as if they formed one spherical lens), the laser beam would be perfectly mode matched to the TEM₀₀ cavity mode. The distance between the pair of cylindrical lenses may determine the amount of light in the ‘+’ mode, which may amount to e.g. 10% of the total power (e.g. 400 μW). One cylindrical lens may be oriented with its axis in-plane and the other out-of-plane. By tuning the position of the cylindrical lenses, the input mode can be engineered to induce up to 2nd order modes. They may be aligned such that all other modes but the TEM₀₀, the TEM₀₂ and the TEM₂₀ modes are suppressed, with an equal transmission level for the latter two. To get an equal balance of TEM₀₂ and TEM₂₀, the cylindrical lenses' positions may be set/tuned to the convergence and divergence of the in-plane and out-of-plane beam waists. The mean resonator waist is positioned exactly where the in-plane and out-of-plane beam waists match. As the beam diverges out of the cavity, its mean waist may also match the cavity mode mean waist. The balancing of the amount of TEM₀₂ and TEM₂₀ relative to TEM₀₀ can be tuned by the spacing between the two cylindrical lenses while keeping its center of mass constant. As each member of the pair is translated symmetrically in opposite directions from this reference configuration, the TEM₀₂ and TEM₂₀ modes are populated with equal amplitudes as observed from the cavity transmission spectrum. Physically, this action translates the beam waists for the horizontal and vertical planes to before and after the cavity waist location. Alternatively, shaping the laser beam such that the laser beam acquires ellipticity is effected by a combination of lenses, wedged prisms, and/or anamorphic prism pairs, wherein optionally an elliptical and/or astigmatic beam is created.

Optionally, the laser beam is polarization filtered prior to directing the laser beam at the optical cavity and the incident signal is polarization filtered, wherein optionally the optical cavity is birefringent.

A limitation of the method in terms of stability may still be posed, for example, by residual fluctuations in the laser beam shape, attributable to the alteration of second-order mode components—affecting the phase reference. To help alleviate this residual limitation, a polarization pre- and post-selection procedure may be utilized, which can be described using the weak-value concept. For this purpose, optionally, the laser beam is polarization filtered prior to directing the laser beam at the optical cavity and the laser beam reflected from the optical cavity is polarization filtered. Optionally, the optical cavity is birefringent. In this way, technical noise that limits system performance can be coherently suppressed. The device preferably comprises a first polarizing beam splitter (or a first polarizer) for polarization filtering the laser beam prior to directing the laser beam to the beam shaper and a second polarizing beam splitter (or a second polarizer) for polarization filtering after emitting the laser beam from the optical cavity, in particular between the detection lens and the detector. The polarization filtering may be used in the method for frequency locking the laser and/or the method for tuning a device for frequency locking the laser.

With the polarization degree of freedom included, the cavity reflection coefficient is replaced by a reflection operator \hat{r} acting on the input polarization state |ψ1 [symbol] . When a post-selection onto state |ψ2 [symbol] is made, the resulting effective reflection coefficient r_{W} is given by the weak-value of the reflection operator

$${r}_{w} = \frac{〈 {ψ}_{2} \vert \hat{r} \vert {ψ}_{1} 〉}{〈 {ψ}_{2} \vert {ψ}_{1} 〉} ≡ 1 - {γ}^{′} \frac{1}{1 - i \frac{δ}{κ / 2}} \qquad ( Equation 1 )$$

Here δ is the laser-cavity frequency detuning, κ is the full-width cavity linewidth and γ′=Aγ, where γ is a dimensionless parameter characterizing the roundtrip losses in the cavity. The ‘amplification’ parameter A depends on the specific post-selection, and it is real-valued for linear polarization states |ψ1 [symbol] and |ψ2 [symbol] . While it is a function of polarizer angles, operationally it can be related to the remaining power faction | [symbol] ψ2|ψ1 [symbol] |²≈1/(2A+1)² after post-selection while the light is off-resonant. The right hand side of Equation 1 is of the same form as the reflection from a regular high-finesse cavity, except with a variable loss parameter γ′ (at fixed κ). Note that γ<1, γ=1, γ>1 and γ>2 can be identified respectively with the under-coupled, impedance-matched, over-coupled, and cavity-gain regimes. The variability of γ′ can be demonstrated experimentally by observing the post-selection dependence of the reflected power from the cavity. The error signal may be given by the imaginary part of the reflection coefficient in Equation 1. Tuning the post-selection to an impedance-matched configuration reduces noise for frequency stabilization purposes. In this configuration, the non-signal-generating beam components incident on the detector are strongly attenuated while signal generating parts are attenuated less, effectively increasing the error signal slope and reducing sensitivity to beam shape or intensity fluctuations.

Optionally, the method further comprises the step:
adjusting the optical cavity to reach the target state by minimizing the error signal.

For example, adjusting the optical cavity includes one or more of the following steps:
adjusting the temperature of the optical cavity,
adjusting the path length of the optical cavity.

By adjusting the optical cavity, e.g., by adjusting the temperature and/or the path length, the optical properties of the optical cavity can be influenced and consequently the geometrical beam shape of the incident signal can be influenced. The error signal is based on the geometrical beam shape of the incident beam.

In an optional embodiment, the optical cavity is the optical cavity of a laser, in particular the optical cavity of a semiconductor laser. The laser may for example be a semiconductor laser and pumping of the laser is effected by an electrical current through the laser cavity. Semiconductor lasers include for example FP (Fabry-Perot) lasers, DFB (Distributed-Feedback) lasers, DBR (Distributed-Bragg reflector) laser or VCSEL (vertical-cavity surface-emitting laser. Other classes of lasers compatible with the presented method include ECDL (external cavity diode lasers) or ECL (external cavity lasers). The pumping of a semiconductor laser can be effected by an electrical current through an active material within the laser cavity.

In general, the path length of the laser cavity, i.e. the optical cavity of the laser, is crucial for the mode distribution of the laser. Optionally, the pumping of the optical cavity may be an operation parameter of the optical cavity. The pumping of the laser depends on the laser technology and can for example be effected by optical pumping via a further light source, e.g. a further laser. Adjusting the pumping can for example include adjusting the electrical current or changing the intensity and/or frequency of the optical pump light.

Optionally, adjusting the optical cavity includes the following step:
adjusting the current of the semiconductor laser. Pumping the semiconductor laser may be effected by an electrical current through the laser cavity. Adjusting the pumping can be effected by adjusting the current.

A specific embodiment of the invention concerns a closed loop control method for controlling an injection-locked laser and a closed loop control system for controlling an injection-locked laser, which is outlined in the following.

The linewidth of a laser is primarily determined by unwanted effects that do not contribute to the stimulated emission of the laser. The laser can be made to copy the phase correlation of another injected ‘seed’ laser beam with a much narrower linewidth. This ideally results in a ‘slave’ laser with the same linewidth as the seed laser. Therefore, injection-locked lasers have a crucial part in modern science and technology, as injection locking enables a narrow linewidth of the laser output. In addition, the injected seed frequency can be altered. The “slave” laser follows the frequency of the injected seed, thus the frequency of the output of the laser can be shifted.

In order to have a stable injection locking and a stable laser output, it is beneficial to control the injection locked laser. For controlling the laser, it is necessary to measure and quantify the output of the laser and to derive an estimator for the deviation of an actual state of the laser relative to a nominal or reference state. A number of methods have been developed over the decades to address the task of finding a suitable measurement and estimator. These include: side-of-fringe intensity methods, polarization based methods, frequency modulation techniques similar to Pound-Drever-Hall (PDH), and lastly, spatial mode interference methods such as tilt locking.

In Diorico, F. et al.: “Laser-cavity locking at the 10\hat{ }(−7) instability scale utilizing beam elipticity.” arXiv preprint arXiv:2203.04550 (2022) a method for locking a laser to an optical cavity is presented. A laser beam is directed at an optical cavity. The laser frequency is in resonance (or near resonance) with the cavity. A reflected beam is focused on a quadrupole photodiode with a lens. The method relies on the interference of the fundamental TEM₀₀ mode of an optical cavity with second order spatial modes, leading to an elliptic beam on the detector. Based on the ellipticity, an error signal is derived, which is used as a feedback for the laser to achieve stable laser cavity locking. The method is referred to as “squash locking”. The publication mentions that a generic squash locking method may be applicable to stabilize laser injection locking. However, the publication does not give a hint how to generalize the disclosed method and does not show how to transpose the disclosed method to injection locking of lasers.

In an embodiment of the invention (see embodiment 1) a method and device for controlling an injection-locked laser in a closed loop, which is robust against alignment drifts and vibrations, is provided.

This is achieved by a closed loop control method for controlling an injection-locked laser, the method comprising the steps:
injecting the laser with an optical seed signal;
propagating at least a portion of an optical output signal from the laser as an incident signal onto a detector;
deriving an error signal based on a geometric beam shape of the incident signal on the detector;
controlling at least one operation parameter of the laser responsive to the error signal.

Further, this is achieved by a closed loop control system for controlling an injection-locked laser (see embodiment 13) comprising:
a laser, wherein the laser during operation is injected with an optical seed signal,
a detector,
optical components for propagating at least a portion of an optical output signal from the laser as an incident signal onto the detector, and
a controller for deriving an error signal based on a geometric beam shape of the incident signal on the detector, wherein the controller is configured for controlling at least one operation parameter of the laser responsive to the error signal.

It is possible to use the laser's own light emission to enhance itself. This method is commonly called self-injection or self-feedback locking. By taking a small portion of a laser's light and feeding a frequency filtered version of it back into itself, emission of the laser into a narrower frequency band is enhanced further. This results into a narrowing of the laser's linewidth. The closed loop control method for controlling an injection-locked laser and the closed loop control system for controlling an injection-locked laser can be used for both injection locking with a seed signal of an external light source and self-injection locked lasers.

The method and the system are initiated or initially calibrated before the method is used. The setpoint or reference point of the control loop (e.g., comprising a PID controller) is set by starting with a laser and an optical seed signal that are locked. The term “locked” is to be understood in a way that the coupling of the optical seed signal to the laser is as desired. For example, the optical seed signal can be perfectly mode matched to the TEM₀₀ laser mode and/or the central frequency of the optical seed signal is in resonance with the laser. In general, at the setpoint a relation of the optical seed signal to the laser is defined. The laser is to be controlled so that the system stabilizes at the setpoint, so that the relation between the laser and the optical seed signal is as constant as possible. This is achieved by deriving an error signal that indicates a deviation from the setpoint. As explained above, the relative change in beam shape with respect to the beam shape at the setpoint can be used to quantify the deviation from the setpoint. In general, the present closed loop control method is not limited to any particular type of control transfer function. Hence, it is not necessary to define a particular setpoint in order to control the at least one operation parameter of the laser.

Instead, it may suffice to drive the laser back into an acceptable range of possible operational states, when the error signal indicates that such a range is left and in which direction.

In general, deriving the error signal based on the geometric beam shape of the incident signal means that the error signal is a function, wherein at least one parameter of the function is a parameter characterizing the geometric beam shape of the incident beam. In particular, the error signal can be directly proportional to a geometric beam ellipticity. The beam ellipticity may be defined according to ISO 11145:2018. Alternatively, the eccentricity may be used. The error signal can optionally be zero at the setpoint. The error signal can have a sign and a magnitude, the sign can optionally indicate the direction of the control, i.e. if an operation parameter of the laser should be increased or decreased. The magnitude of the error signal can be an indication of the magnitude of the necessary change of the at least one operation parameter in order to reach the setpoint.

Optionally, a zero-crossing of the error signal lies in an interval between a minimum and a maximum of the error signal, wherein the interval comprises an error signal value corresponding to a determined beam ellipticity of a substantially circular beam, the incident signal acquiring opposite ellipticities on opposite sides of the resonance can be utilized to determine the error signal, which may be used for locking and thus stabilizing the laser beam.

The determined error signal can be thought of as an interference between the resonating ‘00’ mode that leaks out of the laser, and the second-order ‘+’ mode that promptly reflects from the laser to form a phase reference. This detection modality is insensitive to alignment drifts and fluctuations, since small misalignments simply generate first-order modes in the mode decomposition. Zero-crossing refers to the error signal having a value of zero.

Optionally, the error signal comprises a minimum, which is optionally a global minimum. Optionally, the error signal comprises a maximum, which optionally is a global maximum. Optionally, there is no further extreme value between the minimum and the maximum. Optionally, the error signal comprises an interval extending from the minimum to the maximum. In the interval is a value corresponding to the laser being locked to the seed signal, which is between the minimum and the maximum. Due to the slope of the error-signal, the error signal is used to control the laser to achieve locking of the laser to the optical seed signal.

The detector may be a photodiode, for example an avalanche photodiode. The detector may be a phase plate or mode converter or comprise a phase plate or mode converter. The detector may translate the incident signal into an electrical signal. However, the detector is not limited to electric signals. For example, the detector may be configured to generate an optical signal based on the incident signal and the controller may be configured to derive the error signal based on the optical signal from the detector. In general, the invention is not limited to any particular form of physical signal that the detector generates based on the incident signal.

For example, at least one operation parameter of the laser is one or more of the following:
temperature of a laser cavity,
path length of the laser cavity,
pumping of the laser cavity,
phase of the optical seed signal

In general, the path length of the laser cavity is crucial for the mode distribution of the laser. The temperature influences the path length as the path length can increase or decrease depending on the temperature change due to thermal expansion, in particular in case of a semiconductor laser. The pumping can have an influence on the temperature, thus again the path length might be influenced by the pumping. The temperature can optionally be changed by means of a Peltier element or for example by a separate heating element, such as an electrical heating element, and a separate cooling element, such as, for example, a fan.

The pumping of the laser depends on the laser technology and can for example be effected by optical pumping via a further light source, e.g. a further laser. Adjusting the pumping can for example include adjusting the electrical current or changing the intensity and/or frequency of the optical pump light. The phase of the optical seed signal can be for example adjusted by adjusting the light source of the optical seed signal or by adjusting the optical path of the optical seed signal.

In an optional embodiment, the laser is a semiconductor laser and pumping of the laser is effected by an electrical current through the laser cavity. Semiconductor lasers include for example FP (Fabry-Perot) lasers, DFB (Distributed-Feedback) lasers, DBR (Distributed-Bragg reflector) laser or VCSEL (vertical-cavity surface-emitting laser. Other classes of lasers compatible with the presented method include ECDL (external cavity diode lasers) or ECL (external cavity lasers). The pumping of a semiconductor laser can be effected by an electrical current through an active material within the laser cavity. Adjusting the pumping can be effected by adjusting the current.

For example, the detector is a photodiode array comprising at least three photodiodes and wherein deriving the error signal includes determining the geometric beam shape of the incident signal. By using an array of photodiodes, the geometric beam shape of the incident signal can be estimated. In order to estimate the geometric beam shape, at least three photodiodes need to be used in order to differentiate between first order and second (or higher) order spatial modes. In principle, the more photodiodes are used, the better the signal shape can be approximated. In general, determining the geometric beam shape of the incident signal means that a parameter value of at least one parameter characterizing the geometric beam shape is determined. Preferably, the photodiodes are arranged in a rectangular regular grid. It is beneficial to minimize the distance between the single photodiodes so that the measurement is most sensitive towards changes of the beam shape.

The detector may be a quadrant photodiode and deriving the error signal may include determining a diagonal signal of the quadrant photodiode, which diagonal signal is made up of the difference of the sums of signals from diagonal sensor regions of the quadrant photodiode. In this way, the beam shape of the incident signal, in particular the beam ellipticity, can be estimated particularly easily. In particular, the quadrant photodiode is a photodiode with four split sensor regions. The gaps between the sensor regions may be optimized to be as small as possible. In particular, the quadrant photodiode produces electrical currents proportional to the input light from each of four sensor regions. The signal from each of the sensor regions is labelled A, B, C and D, wherein on the quadrant photodiode, the sensor regions are arranged in the order A, D, B, C (e.g. in clockwise direction). This allows the following operation: SUM=A+B+C+D, LR=(A+C)−(B+D), UD=(A+D)−(C+B), and DIAG=(A+B)−(C+D). The beam ellipticity can be measured using the DIAG operation. A zero DIAG signal indicates the lack of beam ellipticity, meaning the laser beam is circular. A non-zero DIAG signal indicates the presence of an elliptic beam on the quadrant photodiode. Opposite signs of the DIAG signal refer to opposite ellipticities. The quadrant photodiode may be an InGaAs-based or a silicon-based detector. The signals may be converted into voltages (e.g. using standard analog electronics with operational amplifiers).

As discussed above, the method and the system are initiated or initially calibrated before the method is used. During the controlling of the injection-locked laser, the initialized or calibrated properties are constant. The error signal can be initially set by means of the following parameters.

For example, propagating the incident signal includes imposing an incident angle of the incident signal onto the detector. The incident angle has an influence on the beam shape of the incident beam on the detector. E.g. a circular beam will appear to have an elliptic beam shape on the detector when the incident angle differs from 90°. An incident beam with an elliptical cross section can appear to have a circular beam shape on the detector with a suitable incident angle. If the detector is a QPD, the DIAG signal can be set to zero by means of the imposed angle. The imposed angle is set once during calibration and remains constant during operation.

In an optional embodiment, propagating the incident signal includes shaping the incident signal, in particular with at least a lens, preferably with at least a shaping lens, in particular at least a cylindrical lens. By shaping the incident signal, an initial error signal when the laser is locked to the optical seed signal can be calibrated. The error signal may be set to zero initially. If the detector is a QPD, the DIAG signal can be set to zero by means of shaping of the incident signal. This can be achieved, for example, if the detector is a QPD and the incident signal is shaped so that the image of the incident signal on the detector is circular. This way, the DIAG signal is zero. The DIAG signal can optionally be used as the error signal without further operations. The position and alignment of beam shaping optics for shaping the incident signal, in particular the at least one lens, preferably the least one shaping lens, in particular the at least one cylindrical lens, is set once during calibration and remains constant during operation.

In another embodiment, propagating the incident signal includes focusing the incident signal onto the detector with a detection lens, preferably with a convex spherical lens. Optionally, the laser beam is focused and/or diverged in at least a first plane and preferably focused and/or diverged in a second plane (not parallel to the first plane), in particular at a different point along the laser beam's path than the focusing/diverging in the first plane). Focusing the laser beam refers to focusing the laser beam in at least one plane. The position and alignment of detection lens for focusing the incident signal onto the detector, preferably the convex spherical lens, may be set once during calibration and remain constant during operation.

Optionally, propagating the incident signal includes defining an axial distance between the detection lens and the detector such that a transmission peak of the incident signal matches a zero-crossing of the error signal. The transmission peak refers to the resonance of the optical seed signal with the laser. The axial distance between the detection lens and the detector refers to their distance along the path of incident signal. For the method and the device, the positions of the detector and the detection lens are fixed during calibration and remain constant during operation. The relative change of the geometric beam shape of the incident signal is most pronounced at the resonance of the laser with the optical seed signal. Therefore, the method is most sensitive at the transmission peak incident signal, which is also a transmission peak of the optical seed signal.

Optionally, the axial distance may be tuned over a tuning interval to determine a curve of the error signal and to set the axial distance.

In another optional embodiment, propagating the incident signal includes defining an axial distance between the laser and the detector such that a transmission peak of the incident signal matches a zero-crossing of the error signal. The positions of the detector and the laser are fixed during calibration and remain constant during operation. The relative change of the geometric beam shape of the incident signal is most pronounced at the resonance of the laser with the optical seed signal. Therefore, the method is most sensitive at the transmission peak of the incident signal, which is also a transmission peak of the optical seed signal. The distance between the laser and the detector influences the Gouy phase between the TEM₀₀ mode and the second order spatial modes. The resulting image on the detector can therefore be tuned by adjusting the location of the detector relative to the laser. There are axial distances at which the error signal is purely dispersive and other axial distances at which the error signal is purely absorptive or any signal shape in between absorptive and dispersive. Preferably the error signal is dispersive.

Optionally, deriving the error signal may include applying an offset to the error signal. The error signal is derived the following way: the incident signal on the detector leads to a signal per photodiode of the detector. Depending on the estimator for the shape of the incident signal, these signals are used. For example, if the detector is a QPD, the DIAG operation may be used for estimating the ellipticity of the signal. The error signal may be set to zero initially during calibration. This way, the sign of the error signal indicates the direction of the control, e.g. if an operation parameter of the laser should be increased or decreased. Since for example the DIAG operation might lead to a residual signal even if the incident signal is substantially circular, an additional offset can be applied to set the error signal initially to zero at the setpoint.

In another embodiment an imbalanced detection operation can be utilized. For example, instead of the DIAG operation an imbalanced operated IDIAG can be used: IDIAG=ε₁(A+B)−ε₂(C+D), where ε₁/ε₂≠1 and ε₁ and ε₂ can be set initially so as to set the error signal to zero. This allows the background offset of the diagonal channel to be tuned in order to provide a zero-crossing for the error signal at a desired state (e.g., at the setpoint).

The closed loop control method for controlling an injection-locked laser and the closed loop control system for controlling an injection-locked laser can be utilized for continuously shifting the wavelength of the output signal of an injection-locked laser, with the further step: shifting the wavelength of the optical seed signal, wherein the adjustment of the wavelength of the optical seed signal causes a change of the error signal. Shifting the wavelength of the optical seed signal disturbs the locking of the optical seed signal and the laser, thus the error signal changes. The change of the error signal leads to a feedback to the laser in the controlling step of the method as a response. Thereby, the relation of the laser and the optical seed signal is restored at the shifted wavelength of the optical seed signal. This way, the laser output follows the wavelength of the optical seed signal. The error signal indicates whether the laser is operating at its optimal operation parameters for the laser frequency it is injected with. With this information, an extra layer of feedback can be added to dynamically tune operation parameters of the injected laser. This allows the laser to follow the injection frequency throughout its entire operating range. This optimal range allows continuous tuning of the laser frequency without any interruption. This uninterrupted frequency tuning range is often referred to as ‘Mode Hop Free’ region. This is a unique property of a semiconductor laser that can range from a few GHz to tens of GHz. This optimal locking range is determined typically by the set operating current and temperature of the bare semiconductor laser. The initial operation parameters are typically set before during initializing or calibrating the system thus, the range is already pre-determined over a central frequency. This central frequency can be dynamically tuned beyond the Mode Hop Free region if information on the laser's optimal locking range exists. Since the native output mode of a semiconductor laser is highly elliptical and the mode being injected is typically circular (or a different level of ellipticity), there will be an error signal that continuously monitors whether the laser parameters are still within the optimal injection range or at the optimal setpoint. With this, the current or the temperature or both can be dynamically tuned to follow the frequency of the injected signal. This allows to create a widely tunable laser frequency over its entire operating range.

Optionally at least the laser, the optical components, and preferably the detector, are integrated on a micro-optics or silicon photonics platform, preferably a silicon chip. This can for example be done by heterogeneous integration of discrete miniaturized elements on a single system-on-a-chip (SoC). For example, state of the art optical packaging technology and high-precision assembly can be utilized to build the system.

In an optional embodiment the system is integrated in a TO-can package or a butterfly mount (BTF) so that the system is easily compatible with common technologies.

Optionally, the method further comprises the step: centering the output signal on the quadrant photodiode by translating the detection lens and/or the quadrant photodiode in the directions perpendicular to the optical axis of the incident signal such that a left-right signal and/or an up-down signal of the quadrant photodiode are minimized, which left-right (LR) signal and up-down (UD) signal are each made up of the difference of the sums of adjacent sensor regions of the quadrant photodiode, wherein the left-right signal and the up-down signal use the sums of different halves of adjacent sensor regions. Optionally, this is performed iteratively and repeatedly. In this way, the incident signal can be aligned perfectly at the quadrant photodiode, such that the best beam fit over the quadrant photodiode active area is achieved and producing the most accurate error signal. Optionally, the translation occurs in two directions, which are perpendicular to one another and to the optical axis of the laser beam.

A limitation to stability is still posed, for example, by residual fluctuations in the incident signal, attributable to the alteration of second-order mode components—affecting the phase reference. To help alleviate this residual limitation, a polarization pre- and post-selection procedure may be utilized, which can be described using the weak-value concept. For this purpose, optionally, the optical seed signal is polarization filtered prior to directing the optical seed signal at the laser and the optical output signal is polarization filtered. Optionally, the laser comprises a birefringent cavity. In this way, technical noise that limits system performance can be coherently suppressed. The device preferably comprises a first polarizing beam splitter (or a first polarizer) for polarization filtering the optical seed signal prior to directing the optical seed signal to the laser. A second polarizing beam splitter (or a second polarizer) is used for polarization filtering the incident signal, in particular before the detector. The polarization filtering may be used in the closed loop control method for controlling an injection-locked laser and in the closed loop control system for controlling an injection-locked laser.

With the polarization degree of freedom included, the cavity reflection coefficient is replaced by a reflection operator \hat{r}, acting on the input polarization state |ψ1 [symbol] . When a post-selection onto state |ψ2 [symbol] is made, the resulting effective reflection coefficient r_{W} is given by the weak-value of the reflection operator

$${r}_{w} = \frac{〈 {ψ}_{2} \vert \hat{r} \vert {ψ}_{1} 〉}{〈 {ψ}_{2} \vert {ψ}_{1} 〉} ≡ 1 - {γ}^{′} \frac{1}{1 - i \frac{δ}{κ / 2}} \qquad ( Equation 1 )$$

Here δ is the optical seed signal to laser frequency detuning, κ is the full-width laser linewidth and γ′=Aγ, where γ is a dimensionless parameter characterizing the roundtrip losses in the laser. The ‘amplification’ parameter A depends on the specific post-selection, and it is real-valued for linear polarization states |ψ1 [symbol] and |ψ2 [symbol] . While it is a function of polarizer angles, operationally it can be related to the remaining power fraction | [symbol] ψ2|ψ1 [symbol] |²≈1/(2A+1)² after post-selection while the optical seed signal is off-resonant. The [symbol] right hand side of Equation 1 is of the same form as the reflection from a regular high-finesse cavity, except with a variable loss parameter γ′ (at fixed x). Note that γ<1, γ=1, γ>1 and γ>2 can be identified respectively with the under-coupled, impedance-matched, over-coupled, and cavity-gain regimes of the laser. The variability of γ′ can be demonstrated experimentally by observing the post-selection dependence of the reflected power from the laser. The error signal may be given by the imaginary part of the reflection coefficient in Equation 1. Tuning the post-selection to an impedance-matched configuration reduces noise for frequency stabilization purposes. In this configuration, the non-signal-generating beam components incident on the detector are strongly attenuated while signal generating parts are attenuated less, effectively increasing the error signal slope and reducing sensitivity to beam shape or intensity fluctuations.

The optional detection lens may be a convex spherical lens.

The optical seed signal may be shaped prior to being injected into the laser, for example such that the optical seed signal acquires an elliptical geometric beam shape or a circular beam shape.

The method and device can be used with a laser wavelength in a wide range. E.g., the wavelength may be in the ultraviolet range, between 190 nm and 400 nm, the visible range, between 400 nm and 800 nm, in the near-infrared range, between 800 nm and 1800 nm, and/or in the infrared range, between 1800 to at least 3500 nm.

Optionally, the error signal is directly proportional to the geometric beam ellipticity of the incident signal.

Optionally, the error signal is substantially zero for a circular incident signal and/or a circular image of the incident signal on the detector.

A specific embodiment of the invention concerns a method for frequency locking a laser to an optical cavity; a method for tuning a device for frequency locking a laser to an optical cavity; and a device for frequency locking a laser to an optical cavity, which are outlined in the following.

A number of methods have been developed over the decades to address the task of locking lasers to cavities. These include: side-of-fringe intensity methods, polarization based methods, frequency modulation techniques including transmission modulation and the Pound-Drever-Hall (PDH) reflection method, and lastly, spatial mode interference methods.

Certain methods could be preferable based on application, but due to its stability and versatility, the PDH technique—utilizing radio-frequency modulation/demodulation of an optical carrier—has become a general standard. Achieving the most demanding locking stabilities of 1 part in 10⁵-10⁶ of a cavity linewidth has further required additional layers of active feedback mechanisms to reduce the residual amplitude (RAM) modulation which typically limits the lock point stability of a PDH setup. A purely passive and reduced-complexity method that could compete with these highly engineered setups could be beneficial for all applications, especially including space based ones, where electro- and acoustooptic devices used for modulation are undesirable due to power budgets and failure risk.

In an embodiment of the invention, a method and device for frequency locking a laser to an optical cavity and a method for tuning such a device, which achieves a reduced complexity, is purely passive and/or achieves a good laser stabilisation, in particular is less sensitive to alignment drifts and/or comprises a more robust implementation, is provided. In particular a placement of a detection lens and a detector in such a device and method which achieves a better stabilisation is disclosed (see embodiment 15).

This is achieved by a method for frequency locking a laser to an optical cavity (see embodiment 15), comprising the steps:
providing a laser beam from the laser;
shaping the laser beam such that the laser beam acquires ellipticity;
directing the laser beam at the optical cavity;
focusing a laser beam reflected from the optical cavity with a detection lens;
determining an error signal proportional to a beam ellipticity of the focused laser beam with a detector;
locking the laser to the optical cavity based on the error signal;
wherein an axial distance between the detection lens and the detector is such that when the laser provides a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam.

Further, this is achieved by a method for tuning a device for frequency locking a laser to an optical cavity (see embodiment 17),
wherein the device comprises
   a beam shaper for shaping a laser beam such that the laser beam acquires ellipticity,
   an optical cavity for receiving the laser beam after beam shaping,
   a detection lens for focusing a laser beam reflected from the optical cavity,
   a detector for determining an error signal proportional to a beam ellipticity of the laser beam focused by the detection lens;
the method comprising the steps:
   providing a laser beam at a resonance frequency of the optical cavity;
   shaping the laser beam with the beam shaper such that the laser beam acquires ellipticity;
   directing the laser beam at the optical cavity;
   focusing a laser beam reflected from the optical cavity with the detection lens;
   determining an error signal proportional to a beam ellipticity of the focused laser beam with the detector;
   adjusting an axial distance of the detection lens and the detector along an optical axis of the laser beam such that a zero-crossing of the error signal lies in an interval between a minimum and a maximum of the error signal, wherein the interval comprises an error signal value corresponding to a determined beam ellipticity of a substantially circular laser beam.

Further, this is achieved by a device for frequency locking a laser to an optical cavity (see embodiment 27), comprising:
a beam shaper for shaping a laser beam such that the laser beam acquires ellipticity;
an optical cavity for receiving the laser beam after beam shaping;
a detection lens for focusing a laser beam reflected from the optical cavity;
a detector for determining an error signal proportional to a beam ellipticity of the laser beam focused by the detection lens;
wherein an axial distance between the detection lens and the detector is such that on providing the device, in particular the beam shaper, with a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam.

Further, the disclosure concerns a method for the production of a device for frequency locking a laser to an optical cavity, comprising the steps:
providing a beam shaper for shaping a laser beam such that the laser beam acquires ellipticity;
providing an optical cavity for receiving the laser beam after beam shaping;
providing a detection lens for focusing a laser beam reflected from the optical cavity;
providing a detector for determining an error signal proportional to a beam ellipticity of the laser beam focused by the detection lens;
providing a laser beam at a resonance frequency of the optical cavity;
shaping the laser beam with the beam shaper such that the laser beam acquires ellipticity;
directing the laser beam at the optical cavity;
focusing a laser beam reflected from the optical cavity with the detection lens;
determining an error signal proportional to a beam ellipticity of the focused laser beam with the detector;
adjusting an axial distance of the detection lens and the detector along an optical axis of the laser beam such that a zero-crossing of the error signal lies in an interval between a minimum and a maximum of the error signal, wherein the interval comprises an error signal value corresponding to a determined beam ellipticity of a substantially circular laser beam.

To understand the main stabilization method, the Hermite-Gaussian (HG) spatial modes supported by the optical cavity should be recalled. These are a set of Transverse Electromagnetic Modes (TEMₘₙ), that a cavity can support. The subscripts m and n are positive integers for each orthogonal axes in the transverse direction of beam propagation. The sum m+n is called the mode order which can either be odd or even. Starting from a perfectly aligned optical mode coming into an optical cavity, odd modes are induced by misaligning the input beam either tilting or shifting. Even modes on the other hand are induced by focusing/mode mismatch and are independent of tilting or shifting of the beam.

Earlier spatial mode interference implementations relied on inducing 1st order (TEM₀₁ and TEM₁₀) modes by tilting/misaligning the input beam. Here, of interest are the fundamental HG modes TEM₀₀ labeled ‘00’, and specific second-order HG modes, 2^{nd} order TEM₁₁-like modes, that we label ‘+’, which are both even modes. Even modes are induced by mode mismatch and make our method insensitive to misalignment drifts that generate 1st order odd modes. A slightly elliptical beam with a horizontal/vertical orientation can mathematically be decomposed into a main ‘00’ component and a small ‘+’ component. For such a laser beam, the phase difference between these two modes encodes the information about ellipticity. If incident on the optical cavity near a ‘00’ resonance, the two modes acquire a differential phase shift upon reflection, since only one of them resonate given that different order modes are generically non-degenerate. By way of this mechanism, the reflected beam can be made to acquire opposite ellipticities on opposite sides of the resonance of the optical cavity. To harness this effect, the ellipticity of the laser beam reflected from the optical cavity is measured after being focused.

These modes generically possess different resonance frequencies. In terms of the cavity modes, the spatial decomposition of a slightly elliptical beam that is diagonally oriented is given mostly by the TEM₀₀ mode with a small contribution of the ‘TEM₁₁’ 2nd order mode. For such a beam, the phase difference between these two modes encodes the information about the departure from circularity. If incident on the cavity near one of its fundamental frequencies, the two modes naturally acquire a differential phase shift since only one of them resonate. This results into a shape change in the reflected beam. By way of this mechanism, the reflected beam can be made to acquire opposite ellipticities on opposite sides of the resonance, thus, generating a determinable error signal. To harness this feature, an error signal proportional to the beam ellipticity of the reflected laser beam is used and the axial distance of the detector and the detection lens has to be adjusted appropriately. By setting the axial distance such that on providing the beam shaper with a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular beam, the reflected beam acquiring opposite ellipticities on opposite sides of the resonance can be utilized to determine the laser beams deviation and/or drift, which may be used for locking and thus stabilizing the laser beam. The determined error signal can be thought of as an interference between the resonating ‘00’ mode that leaks out of the cavity, and the second-order ‘+’ mode that promptly reflects from the optical cavity to form a phase reference. This detection modality is insensitive to alignment drifts and fluctuations, since small misalignments simply generate first-order modes in the mode decomposition.

The optical cavity may be a linear cavity or a ring cavity. E.g., a ring cavity may be used where the incident and reflected beams are traveling on separate paths. The optical cavity can for example be a two-mirror cavity or a three-mirror cavity. However, a cavity with any number of mirrors and any geometry can be used. If a two-mirror (standing wave) cavity is used as the optical cavity, the reflected beam can be separated from the incident path e.g. by using a Faraday circulator or with a quarter wave plate and a polarizing beam splitter. The optical cavity may be a free-space cavity or a non-free-space cavity, such as a micro-chip-based optical cavity. E.g., the optical cavity can be a whispering gallery mode resonator, where the light circulates around the perimeter (inside the material) of a sphere or a toroid. The optical cavity could also be a fiber ring, into which light could be coupled evanescently. This coupling can for example be accomplished by using a prism, where the evanescent tails during total internal from the prism couples light in and out of the optical cavity. Thus, the prism effectively interfaces the waveguide-like structures into free space optics. The prism may look like the input mirror of a free space cavity, albeit, one with very elliptical mode structures. In this case, the input mode shaping should prepare beam profiles that are further squashed with respect to the native modes of the microresonator-prism assembly.

The method and device can be used with a laser beam wavelength in a wide range. E.g., the wavelength may be in the ultraviolet range, between 190 nm and 400 nm, the visible range, between 400 nm and 800 nm, in the near-infrared range, between 800 nm and 1800 nm, and/or in the infrared range, between 1800 to at least 3500 nm. Optionally, the error signal is directly proportional to the beam ellipticity of the focused laser beam. Optionally, the error signal is substantially zero for a circular laser beam. Optionally, the laser is locked to the optical cavity based on the error signal by feeding the error signal back to the laser current. Optionally, the device comprises the laser. The locking is based on monitoring the change in the ellipticity of the laser beam reflected from the optical cavity.

Focusing the laser beam refers to focusing the laser beam in at least one plane. Providing a laser beam at a resonance frequency of the optical cavity preferably includes the step of tuning the laser (in particular to find the resonance frequency). Optionally, the method for tuning the device comprises (without beam shaping, i.e. prior to inserting the beam shaper into the device):
(perfectly) coupling the laser beam into the cavity and measuring the reflected beam properties, in particular with a CCD camera
inserting the beam shaper into the device.

Optionally, the method for tuning the device comprises: measuring the in-plane beam waist and the out-of-plane beam waist of the laser beam reflected from the optical cavity at more than one distance.

The axial distance between the detection lens and the detector refers to their distance along the path of the laser beam. For the method and the device for frequency locking the laser to an optical cavity, the positions of the detector and the detection lens may be fixed. For the method for adjusting and producing the device, the detector and/or the detection lens may be moved. Zero-crossing refers to the error signal having a value of zero. Optionally, the minimum is a global minimum and/or the maximum is a global maximum. Optionally, there is no further extreme value between the minimum and the maximum. Optionally, the interval extends from the minimum to the maximum. In the interval comprising the error signal value corresponding to a circular laser beam (on providing a laser beam with a frequency at a resonance frequency) and between the minimum and the maximum, due to the slope of the error-signal, the error signal can be used for locking the laser. Optionally, the resonance frequency of the optical cavity is the frequency of the TEM₀₀ resonance or the resonance frequency of the TEM₀₂ or TEM₂₀ or TEM₁₁ resonance. Optionally, the axial distance may be tuned over a tuning interval to determine a curve of the error signal and to set the axial distance.

It is preferred if the detector is a quadrant photodiode and the error signal is determined by a diagonal signal of the quadrant photodiode, which diagonal signal is made up of the difference of the sums of signals from diagonal sensor regions of the quadrant photodiode. In this way, an error signal corresponding to the beam ellipticity can be achieved particularly easy. In particular, the quadrant photodiode is a photodiode with four split sensor regions. The gaps between the sensor regions may be optimized to be as small as possible. In particular, the quadrant photodiode produces electrical currents proportional to the input light from each of four sensor regions. The signal from each of the sensor regions is labeled A, B, C and D, wherein on the quadrant photodiode, the sensor regions are arranged in the order A, D, B, C (e.g. in clockwise direction). This allows the following operation: SUM=A+B+C+D, LR=(A+C)−(B+D), UD=(A+D)−(C+B), and DIAG=(A+B)−(C+D). The beam ellipticity can be measured using the DIAG operation. A zero DIAG signal indicates the lack of beam ellipticity, meaning the laser beam is circular. A non-zero DIAG signal indicates the presence of an elliptic beam on the quadrant photodiode. The quadrant photodiode may be an InGaAs-based or a silicon-based detector. The signals may be converted into voltages (e.g. using standard analog electronics with operational amplifiers).

A limitation to stability is still posed, for example, by residual fluctuations in the incident beam shape, attributable to the alteration of second-order mode components—affecting the phase reference. To help alleviate this residual limitation, a polarization pre- and post-selection procedure may be utilized, which can be described using the weak-value concept. For this purpose, optionally, the laser beam is polarization filtered prior to directing the laser beam at the optical cavity and the laser beam reflected from the optical cavity is polarization filtered. Optionally, the optical cavity is birefringent. In this way, technical noise that limits system performance can be coherently suppressed. The device preferably comprises a first polarizing beam splitter (or a first polarizer) for polarization filtering the laser beam prior to directing the laser beam to the beam shaper and a second polarizing beam splitter (or a second polarizer) for polarization filtering after emitting the laser beam from the optical cavity, in particular between the detection lens and the detector. The polarization filtering may be used in the method for frequency locking the laser and/or the method for tuning a device for frequency locking the laser.

With the polarization degree of freedom included, the cavity reflection coefficient is replaced by a reflection operator \hat{r} acting on the input polarization state |ψ1 [symbol] . When a post-selection onto state |ψ2 [symbol] is made, the resulting effective reflection coefficient r_{W} is given by the weak-value of the reflection operator

$${r}_{w} = \frac{〈 {ψ}_{2} \vert \hat{r} \vert {ψ}_{1} 〉}{〈 {ψ}_{2} \vert {ψ}_{1} 〉} ≡ 1 - {γ}^{′} \frac{1}{1 - i \frac{δ}{κ / 2}} \qquad ( Equation 1 )$$

Here δ is the laser-cavity frequency detuning, κ is the full-width cavity linewidth and γ′=Aγ, where γ is a dimensionless parameter characterizing the roundtrip losses in the cavity. The ‘amplification’ parameter A depends on the specific post-selection, and it is real-valued for linear polarization states |ψ1 [symbol] and |ψ2 [symbol] . While it is a function of polarizer angles, operationally it can be related to the remaining power fraction | [symbol] ψ2|ψ1 [symbol] |²≈1/(2A+1)² after post-selection while the light is off-resonant. The right hand side of Equation 1 is of the same form as the reflection from a regular high-finesse cavity, except with a variable loss parameter γ′ (at fixed κ). Note that γ<1, γ=1, γ>1 and γ>2 can be identified respectively with the under-coupled, impedance-matched, over-coupled, and cavity-gain regimes. The variability of γ′ can be demonstrated experimentally by observing the post-selection dependence of the reflected power from the cavity. The error signal may be given by the imaginary part of the reflection coefficient in Equation 1. Tuning the post-selection to an impedance-matched configuration reduces noise for frequency stabilization purposes. In this configuration, the non-signal-generating beam components incident on the detector are strongly attenuated while signal generating parts are attenuated less, effectively increasing the error signal slope and reducing sensitivity to beam shape or intensity fluctuations.

Referring now to the method for tuning the device, it is preferable if adjusting an axial distance of the detection lens and the detector along an optical axis of the laser beam such that a zero-crossing of the error signal lies in an interval between a minimum and a maximum of the error signal, wherein the interval comprises an error signal value corresponding to a determined beam ellipticity of a substantially circular laser beam comprises:
adjusting the axial distance of the detection lens and the detector along an optical axis of the laser beam such that a transmission peak of the laser beam reflected from the cavity matches a zero-crossing of the error signal. The transmission peak corresponds to a reflection minimum, i.e. the SUM channel of the quadrant photodiode will give a dip (since the SUM channel of the quadrant photodiode in particular measures the reflection curve). In this way, a baseline offset of the error signal due to the optical cavity's natural astigmatism can be corrected. The baseline offset also gives rise to a shift of the transmission peak from the error signal zero-crossing. Hence, the axial QPD location can be adjusted until the transmission peak and the error signal zero-crossing match. In absence of this matching, a cross-coupling of intensity noise to frequency noise emerges. The zero-crossing or the error signal can be made to match the transmission plateau by moving the detector away or toward the detection lens or vice versa. This position can for example be found iteratively, i.e. experimentally by fine tuning the detector's and/or detection lens' position. It is also preferable in the context of the method and the device for frequency locking the laser, if the axial distance of the detection lens and the detector along the optical axis of the laser beam is such that a transmission peak of the laser beam reflected from the cavity substantially matches or is within ±5% or within ±2% or within ±1% of a zero-crossing of the error signal, when the laser provides a laser beam at a resonance frequency of the optical cavity. This may also replace the feature whereby “an axial distance between the detection lens and the detector is such that when the laser provides a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam”. There may be a baseline offset of the error signal. Naively and without knowledge of astimagtism, one would believe that this would not produce the best results. However, this criterion helps produce the best possible result that goes beyond that of the Pound-Drever-Hall method.

Optionally, adjusting an axial distance of the detection lens and the detector along an optical axis of the laser beam such that a zero-crossing of the error signal lies in an interval between a minimum and a maximum of the error signal, wherein the interval comprises an error signal value corresponding to a determined beam ellipticity of a substantially circular laser beam comprises:
adjusting the axial distance such that an in-plane beam waist and an out-of-plane beam waist of the laser beam reflected from the cavity match with a beam waist of a resonance cavity mode of the optical cavity (in particular with a cavity mode mean beam waist, which is the average beam waist of its in- and out-of-plane beam waist). Optionally, this is conducted prior to adjusting the axial distance of the detection lens and the detector along the optical axis of the laser beam such that the transmission peak of the laser beam reflected from the cavity matches the zero-crossing of the error signal. Optionally, additionally or alternatively, the axial distance is adjusted such that the in-plane beam waist and out-of-plane beam waist of the laser beam reflected from the cavity match (with each other). A baseline offset on the error signal is attributable to an axial displacement of the detector location from the location where the beam assumes a circular profile (disregarding astigmatism). The axial distance can be chosen such that this baseline offset is eliminated. This match of the beam waists can be used as a first approximation before matching the transmission peak and the zero-crossing or can be used itself. If there is no astigmatism, these two will give the same result. In this case there is no residual astigmatism in the modes, so zeroing the baseline automatically puts one in at the plateau of the transmission. It is also preferable in the context of the method and the device for frequency locking the laser, if the axial distance of the detector and the detection lens is such that an in-plane beam waist and an out-of-plane beam waist of the laser beam reflected from the cavity match with a beam waist of a resonance cavity mode of the optical cavity or are within ±5% or within ±2% or within ±1% of the beam waist of the resonance cavity mode of the optical cavity. This may also replace the feature whereby “an axial distance between the detection lens and the detector is such that when the laser provides a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam”.

Optionally, the detector is a quadrant photodiode and the error signal is determined by a diagonal signal of the quadrant photodiode, which diagonal signal is made up of the difference of the sums of signals from diagonal sensor regions of the quadrant photodiode

Optionally, the method further comprises the step:
centering the laser beam on the quadrant photodiode by translating the detection lens and/or the quadrant photodiode in the directions perpendicular to the optical axis of the laser beam such that a left-right signal and/or an up-down signal of the quadrant photodiode are minimized, which left-right (LR) signal and up-down (UD) signal are each made up of the difference of the sums of adjacent sensor regions of the quadrant photodiode, wherein the left-right signal and the up-down signal use the sums of different halves of adjacent sensor regions. Optionally, this is performed iteratively and repeatedly. In this way, the laser beam can be aligned perfectly at the quadrant photodiode, such that the best beam fit over the quadrant photodiode active area is achieved and producing the most accurate error signal.

Optionally, the translation occurs in two directions, which are perpendicular to one another and to the optical axis of the laser beam.

Optionally, the step of adjusting an axial distance of the detection lens and the quadrant photodiode along an optical axis of the laser beam such that the transmission peak of the laser beam reflected from the cavity matches the zero-crossing of the error signal and the step of centering the laser beam on the quadrant photodiode are conducted iteratively (i.e. alternatively repeatingly, i.e. in turn repeatingly). For every adjustment in the axial distance, the left-right and the up-down signals can to be minimized. By repeating this process, the zero-crossing can be optimized to match exactly the transmission plateau.

Referring to all methods and device disclosed herein, it is preferable if the detection lens is a convex spherical lens.

Further, it is preferable if the laser beam is propagated in a polarizing fiber and is optionally emitted from a fiber collimator, prior to shaping the laser beam such that the laser beam acquires ellipticity. The fiber collimator may have an adjustable focus.

It is preferable, if shaping the laser beam such that the laser beam acquires ellipticity is effected at least by a pair of cylindrical lenses (which optionally which have focusing axes oriented non-parallelly, in particular perpendicularly, to each other). Optionally, the two cylindrical lenses have identical focal lengths, further optionally with one oriented horizontally and the other vertically. The focal length is optionally chosen such that if the two lenses were co-located (as if they formed one spherical lens), the incident beam would be perfectly mode matched to the TEM₀₀ cavity mode. The distance between the pair of cylindrical lenses may determine the amount of light in the ‘+’ mode, which may amount to e.g. 10% of the total power (e.g. 400 μW). One cylindrical lens may be oriented with its axis in-plane and the other out-of-plane. By tuning the position of the cylindrical lenses and optionally the fiber collimator, the input mode can be engineered to induce up to 2nd order modes. They may be aligned such that all other modes but the TEM₀₀, the TEM₀₂ and the TEM₂₀ modes are suppressed, with an equal transmission level for the latter two. To get an equal balance of TEM₀₂ and TEM₂₀, the cylindrical lenses' positions may be set/tuned to the convergence and divergence of the in-plane and out-of-plane beam waists. The mean resonator waist is positioned exactly where the in-plane and out-of-plane beam waists match. As the beam diverges out of the cavity, its mean waist may also match the cavity mode mean waist. The balancing of the amount of TEM₀₂ and TEM₂₀ relative to TEM₀₀ can be tuned by the spacing between the two cylindrical lenses while keeping its center of mass constant. As each member of the pair is translated symmetrically in opposite directions from this reference configuration, the TEM₀₂ and TEM₂₀ modes are populated with equal amplitudes as observed from the cavity transmission spectrum. Physically, this action translates the beam waists for the horizontal and vertical planes to before and after the cavity waist location. Alternatively, shaping the laser beam such that the laser beam acquires ellipticity is effected by a combination of lenses, wedged prisms, and/or anamorphic prism pairs, wherein optionally an elliptical and/or astigmatic beam is created.

Referring now to the device for frequency locking a laser to an optical cavity, it is preferable if the detector is a quadrant photodiode. Optionally the detector is configured to determine the error signal by a diagonal signal of the quadrant photodiode, which diagonal signal is made up of the difference of the sums of signals from diagonal sensor regions of the quadrant photodiode.

Optionally, the beam shaper comprises a pair of cylindrical lenses, which have focusing axes oriented in non-parallel directions, in particular perpendicularly, to each other.

By way of example, the disclosure is further explained with respect to selected embodiments 1 to 29 below, which are also shown in the drawings. However, these embodiments shall not be considered limiting for the disclosure.
1. A closed loop control method for controlling an injection-locked laser, the method comprising the steps:
   injecting the laser with an optical seed signal;
   propagating at least a portion of an optical output signal from the laser as an incident signal onto a detector;
   deriving an error signal based on a geometric beam shape of the incident signal on the detector;
   controlling at least one operation parameter of the laser responsive to the error signal.
2. The method according to embodiment 1, wherein the at least one operation parameter of the laser is one or more of the following:
   temperature of a laser cavity,
   path length of the laser cavity,
   pumping of the laser cavity,
   phase of the optical seed signal.
3. The method according to embodiment 1 or 2, wherein the laser is a semiconductor laser and pumping of the laser is effected by an electrical current through the laser cavity.
4. The method according to any one of the previous embodiments, wherein the detector is a photodiode array comprising at least three photodiodes and wherein deriving the error signal includes determining the geometric beam shape of the incident signal.
5. The method according to any one embodiments 1 to 3, wherein the detector is a quadrant photodiode and wherein deriving the error signal includes determining a diagonal signal of the quadrant photodiode, which diagonal signal is made up of the difference of the sums of signals from diagonal sensor regions of the quadrant photodiode.
6. The method according to any one of the previous embodiments, wherein propagating the incident signal includes imposing an incident angle of the incident signal onto the detector.
7. The method according to any one of the previous embodiments, wherein propagating the incident signal includes shaping the incident signal, in particular with at least a lens, preferably with at least a shaping lens, in particular at least a cylindrical lens.
8. The method according to any one of the previous embodiments, wherein propagating the incident signal includes focusing the incident signal onto the detector with a detection lens (33), preferably with a convex spherical lens.
9. The method according to embodiment 8, wherein propagating the incident signal includes defining an axial distance between the detection lens and the detector such that a transmission peak of the incident signal matches a zero-crossing of the error signal.
10. The method according to any one of the previous embodiments, wherein propagating the incident signal includes defining an axial distance between the laser and the detector such that a transmission peak of the incident signal matches a zero-crossing of the error signal.
11. The method according to any one of the previous embodiments, wherein deriving the error signal includes applying an offset to the error signal.
12. A method for continuously shifting the wavelength of the output signal of an injection-locked laser with the method according to any of embodiments 1 to 12 further comprising the step:
   shifting the wavelength of the optical seed signal, wherein the adjustment of the wavelength of the optical seed signal (10) causes a change of the error signal.
13. A closed loop control system for controlling an injection-locked laser comprising:
   a laser, wherein the laser during operation is injected with an optical seed signal,
   a detector,
   optical components for propagating at least a portion of an optical output signal from the laser as an incident signal onto the detector, and
   a controller for deriving an error signal based on a geometric beam shape of the incident signal on the detector, wherein the controller is configured for controlling at least one operation parameter of the laser responsive to the error signal.
14. The control system according to embodiment 13, wherein at least the laser, the optical components, and preferably the detector, are integrated on a micro-optics or silicon photonics platform, preferably a silicon chip.
15. A method for frequency locking a laser to an optical cavity, comprising the steps:
   providing a laser beam from the laser;
   shaping the laser beam such that the laser beam acquires ellipticity;
   directing the laser beam at the optical cavity;
   focusing a laser beam reflected from the optical cavity with a detection lens;
   determining an error signal proportional to a beam ellipticity of the focused laser beam with a detector;
   locking the laser to the optical cavity based on the error signal;
   wherein an axial distance between the detection lens and the detector is such that when the laser provides a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam.
16. The method according to embodiment 15, wherein the detector is a quadrant photodiode and the error signal is determined by a diagonal signal of the quadrant photodiode, which diagonal signal is made up of the difference of the sums of signals from diagonal sensor regions of the quadrant photodiode.
17. A method for tuning a device for frequency locking a laser to an optical cavity,
   wherein the device comprises
      a beam shaper for shaping a laser beam such that the laser beam acquires ellipticity,
      an optical cavity for receiving the laser beam after beam shaping,
      a detection lens for focusing a laser beam reflected from the optical cavity,
      a detector for determining an error signal proportional to a beam ellipticity of the laser beam focused by the detection lens;
   the method comprising the steps:
      providing a laser beam at a resonance frequency of the optical cavity;
      shaping the laser beam with the beam shaper such that the laser beam acquires ellipticity;
      directing the laser beam at the optical cavity;
      focusing a laser beam reflected from the optical cavity with the detection lens;
      determining an error signal proportional to a beam ellipticity of the focused laser beam with the detector;
      adjusting an axial distance of the detection lens and the detector along an optical axis of the laser beam such that a zero-crossing of the error signal lies in an interval between a minimum and a maximum of the error signal, wherein the interval comprises an error signal value corresponding to a determined beam ellipticity of a substantially circular laser beam.
18. The method according to embodiment 17, wherein adjusting the axial distance of the detection lens and the detector comprises:
   adjusting the axial distance of the detection lens and the detector along an optical axis of the laser beam such that a transmission peak of the laser beam reflected from the optical cavity matches a zero-crossing of the error signal.
19. The method according to embodiment 17 or 18, wherein adjusting the axial distance of the detection lens and the detector comprises, optionally prior to adjusting the axial distance of the detection lens and the detector along the optical axis of the laser beam such that the transmission peak of the laser beam reflected from the optical cavity matches the zero-crossing of the error signal:
   adjusting the axial distance such that an in-plane beam waist and an out-of-plane beam waist of the laser beam reflected from the optical cavity match with a beam waist of a resonance cavity mode of the optical cavity.
20. The method according to any one of embodiments 17 to 19, wherein the detector is a quadrant photodiode and the error signal is determined by a diagonal signal of the quadrant photodiode, which diagonal signal is made up of the difference of the sums of signals from diagonal sensor regions of the quadrant photodiode.
21. The method according to embodiment 20, further comprising the step:
   centering the laser beam on the quadrant photodiode by translating the detection lens and/or the quadrant photodiode in the directions perpendicular to the optical axis of the laser beam such that a left-right signal and/or an up-down signal of the quadrant photodiode are minimized, which left-right signal and up-down signal are each made up of the difference of the sums of adjacent sensor regions of the quadrant photodiode, wherein the left-right signal and the up-down signal use the sums of different halves of adjacent sensor regions.
22. The method according to embodiment 7, wherein the step of adjusting an axial distance of the detection lens and the quadrant photodiode along the optical axis of the laser beam such that the transmission peak of the laser beam reflected from the optical cavity matches the zero-crossing of the error signal and the step of centering the laser beam on the quadrant photodiode are conducted iteratively.
23. The method according to any one of the embodiments 15 to 22, wherein the detection lens is a convex spherical lens.
24. The method according to any one of the embodiments 15 to 23, wherein the laser beam is propagated in a polarizing fiber and is optionally emitted from a fiber collimator, prior to shaping the laser beam such that the laser beam acquires ellipticity.
25. The method according to any one of the embodiments 15 to 24, wherein shaping the laser beam such that the laser beam acquires ellipticity is effected by a pair of cylindrical lenses, which have focusing axes oriented non-parallelly, in particular perpendicularly, to each other and/or shaping the laser beam such that the laser beam acquires ellipticity is effected by a combination of lenses, wedged prisms, and/or anamorphic prism pairs, wherein an elliptical or astigmatic beam is created.
26. The method according to any one of the embodiments 15 to 25, wherein the laser beam is polarization filtered prior to directing the laser beam at the optical cavity and the laser beam reflected from the optical cavity is polarization filtered, wherein optionally the optical cavity is birefringent.
27. A device for frequency locking a laser to an optical cavity, comprising:
   a beam shaper for shaping a laser beam such that the laser beam acquires ellipticity;
   an optical cavity for receiving the laser beam after beam shaping;
   a detection lens for focusing a laser beam reflected from the optical cavity;
   a detector for determining an error signal proportional to a beam ellipticity of the laser beam focused by the detection lens;
   wherein an axial distance between the detection lens and the detector is such that on providing the beam shaper with a laser beam at a resonance frequency of the optical cavity, a zero-crossing of the error signal lies in an interval between a minimum and a maximum of the error signal, wherein the interval comprises an error signal value corresponding to a determined beam ellipticity of a substantially circular laser beam.
28. The device according to embodiment 27, wherein the detector is a quadrant photodiode,
   wherein optionally the detector is configured to determine the error signal by a diagonal signal of the quadrant photodiode, which diagonal signal is made up of the difference of the sums of signals from diagonal sensor regions of the quadrant photodiode.
29. The device according to any of embodiments 27 or 28, wherein the beam shaper comprises a pair of cylindrical lenses, which have focusing axes oriented non-parallelly, in particular perpendicularly, to each other.

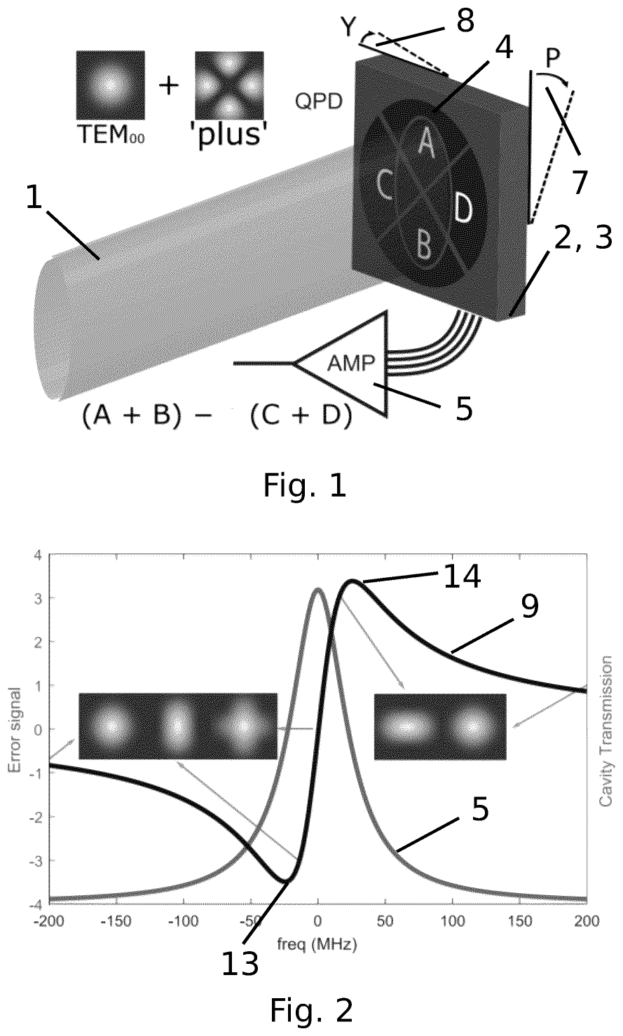

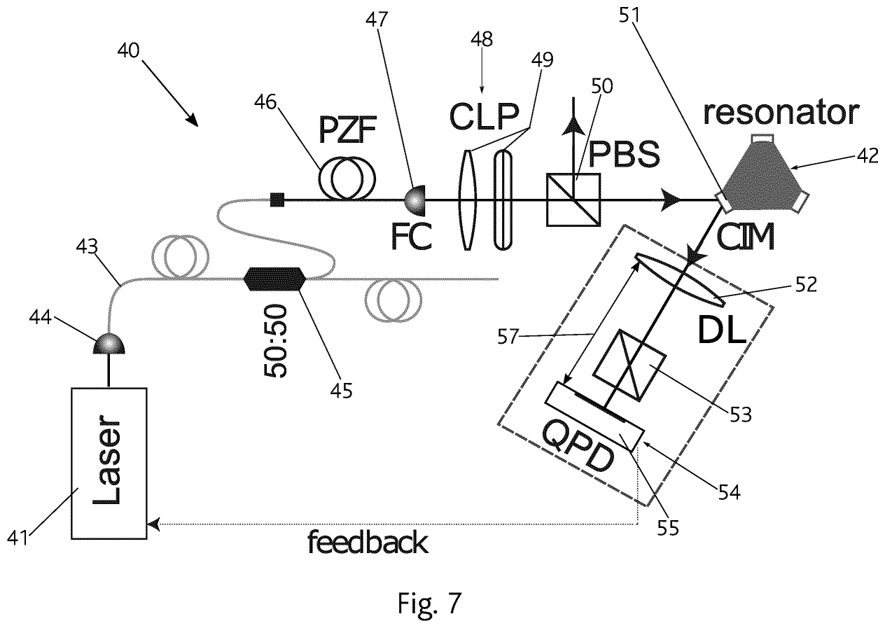

By way of example, the disclosure is further explained with respect to some selected embodiments shown in the drawings for purposes of illustration. However, these embodiments shall not be considered limiting for the disclosure. FIGS. 1 to 6 relate to embodiments 1 to 14, whereas FIGS. 7 to 15c relate to embodiments 15 to 29.

FIG. 1 schematically illustrates a beam ellipticity detection using a quadrant photodiode.

FIG. 2 illustrates an error signal as a function of the detuning of the laser relative to an optical seed signal.

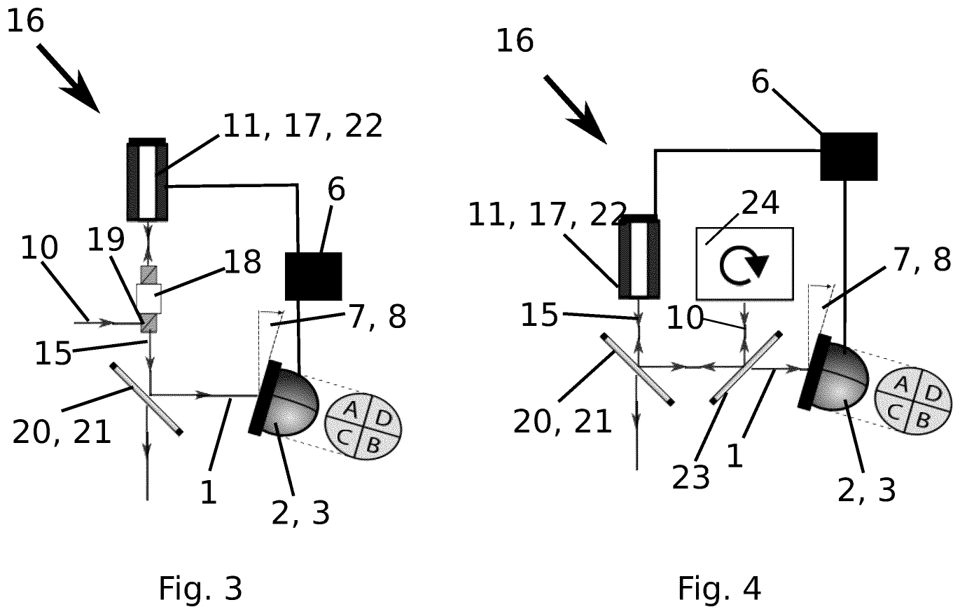

FIG. 3 schematically shows an example of a closed loop control system for controlling an injection-locked laser with an external optical seed signal.

FIG. 4 schematically shows an example of a closed loop control system for controlling a self-injection-locked laser, using a portion of the output signal of the laser as the optical seed signal.

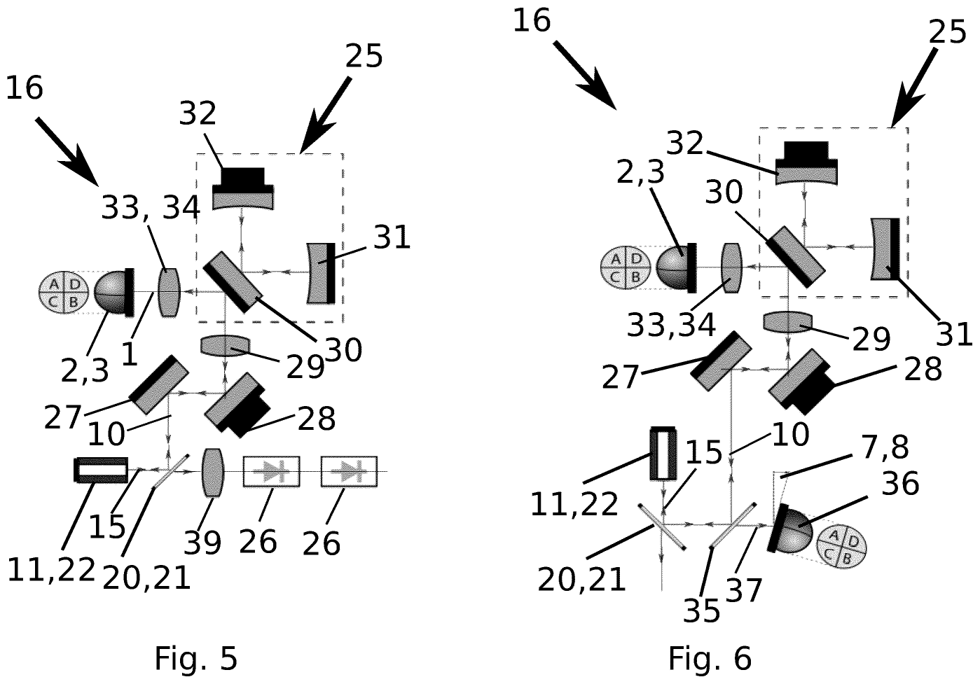

FIG. 5 shows an example of a closed loop control system for controlling a self-injection-locked laser with an external cavity providing the reflected signal for self-injection.

FIG. 6 shows an example of a closed loop control system for controlling a self-injection-locked with an external cavity providing the reflected signal for self-injection, with a second detector between the laser and the external cavity.

FIG. 7 schematically shows an embodiment of the device for frequency locking a laser to an optical cavity.

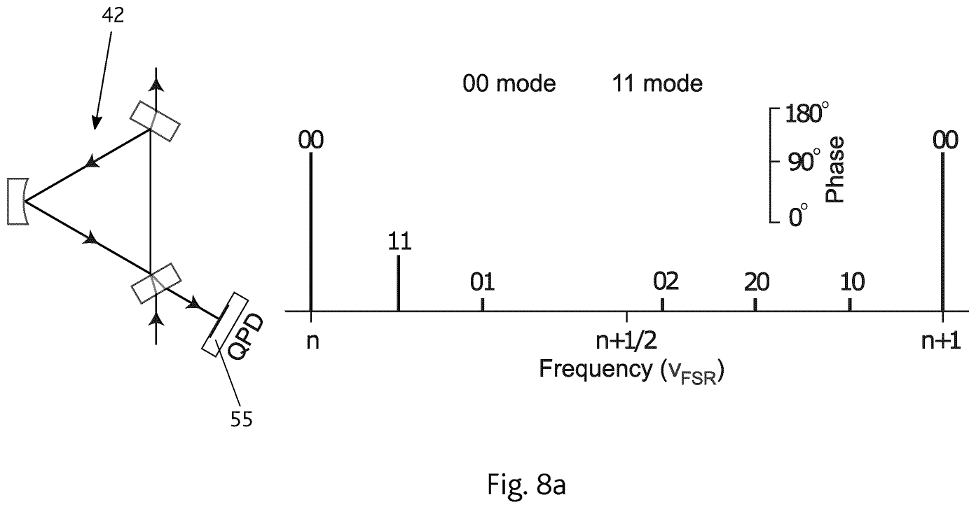

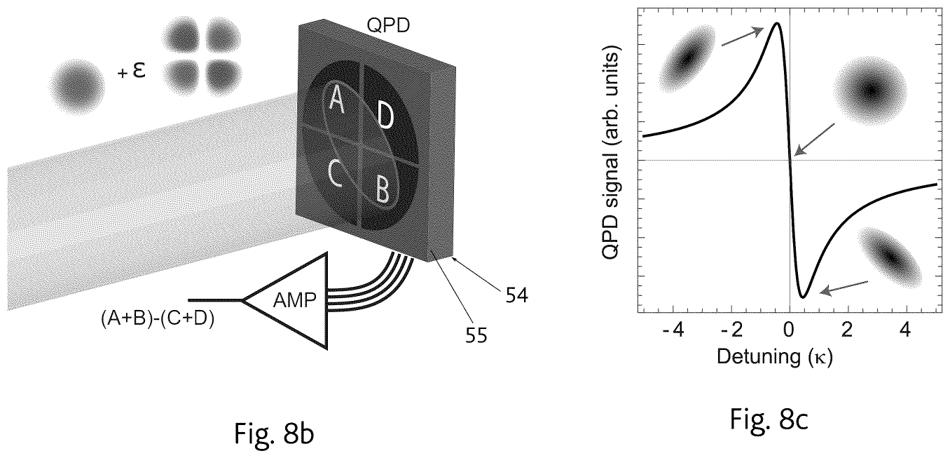

FIG. 8a schematically shows a triangular ring cavity geometry and its relevant Hermite-Gaussian mode resonances.

FIG. 8b illustrates the beam ellipticity detection using a quadrant photodiode.

FIG. 8c illustrates the frequency dependence of the error signal.

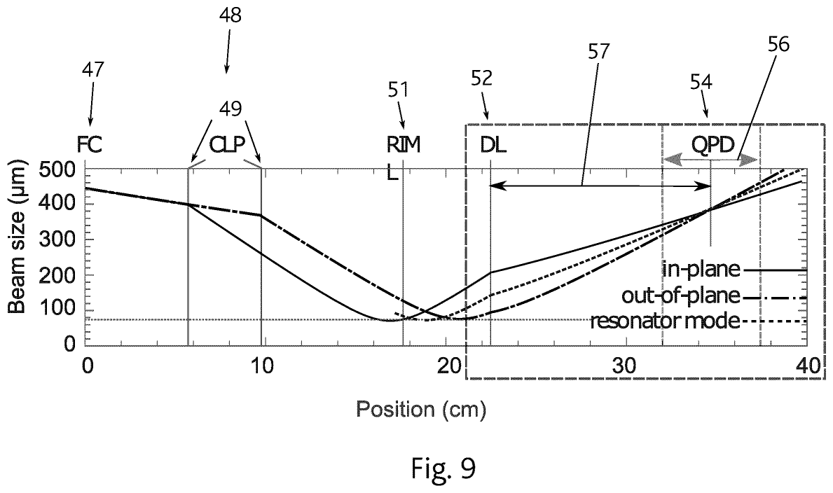

FIG. 9 illustrates the location of the relevant elements in the beam path and the resulting beam properties in the embodiment of FIG. 7.

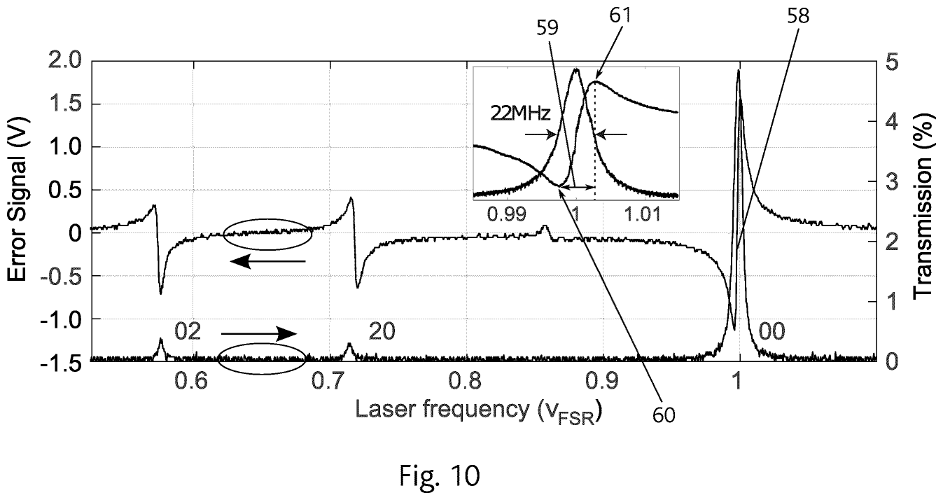

FIG. 10 illustrates the error signal and cavity transmission in the embodiment of FIG. 7.

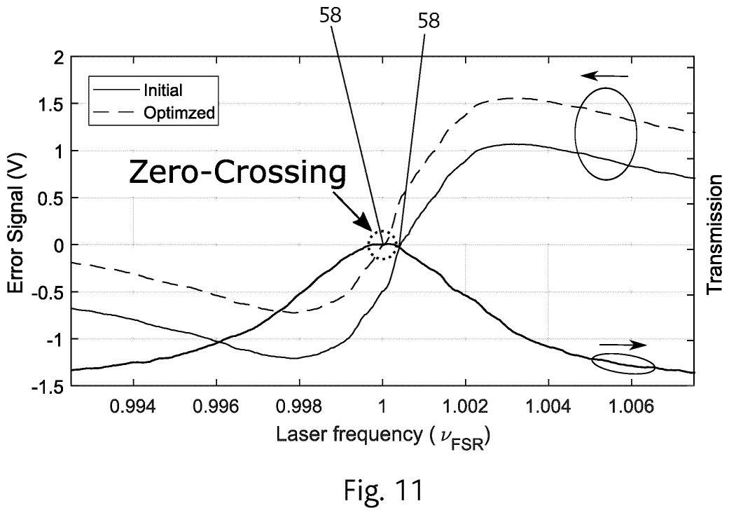

FIG. 11 illustrates the error signal and the transmission.

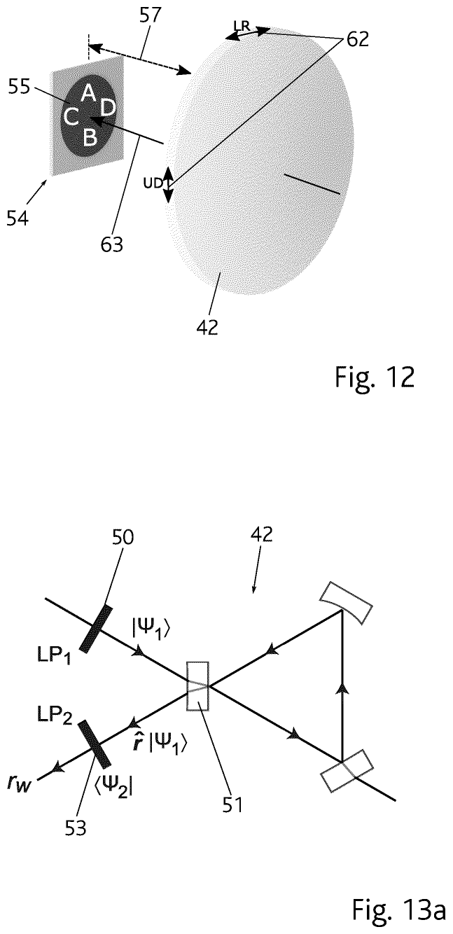

FIG. 12 schematically illustrates an axial distance between the detection lens and the detector.

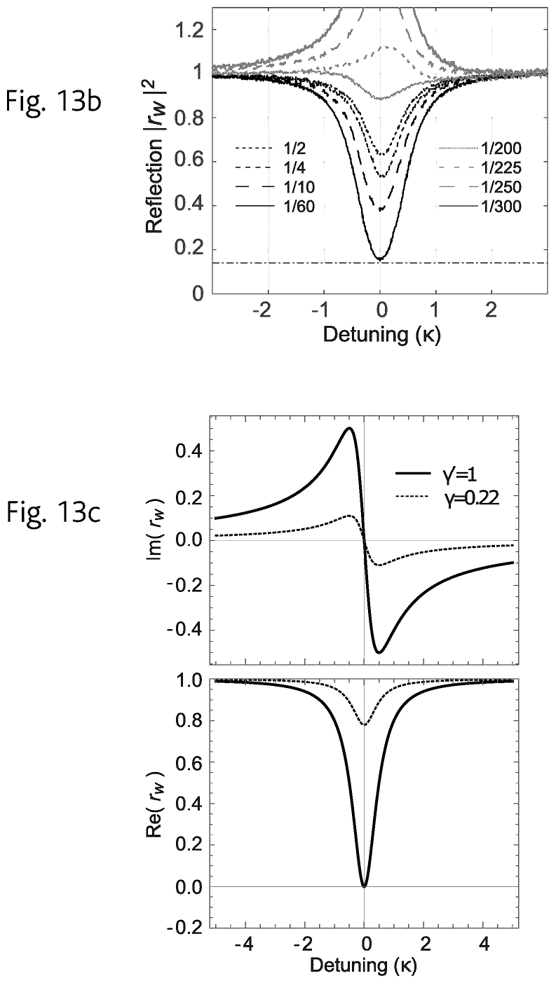

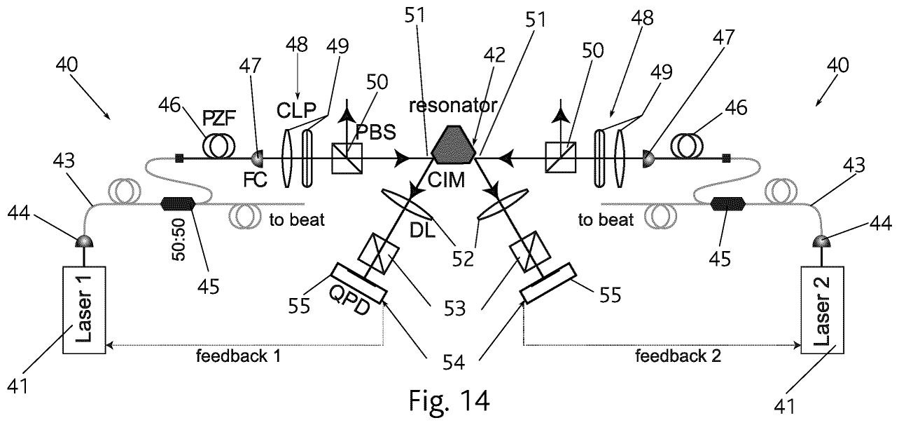

FIG. 13a illustrates the use of a first and a second polarizers in the embodiment of FIGS. 7 and 14.

FIG. 13b illustrates the measured normalized reflection power for different post-selection configurations.

FIG. 13c illustrates the real and imaginary parts of the obtained weak value.

FIG. 14 illustrates two copies of the lockup setup, which was used to demonstrate the performance of the stabilization scheme.

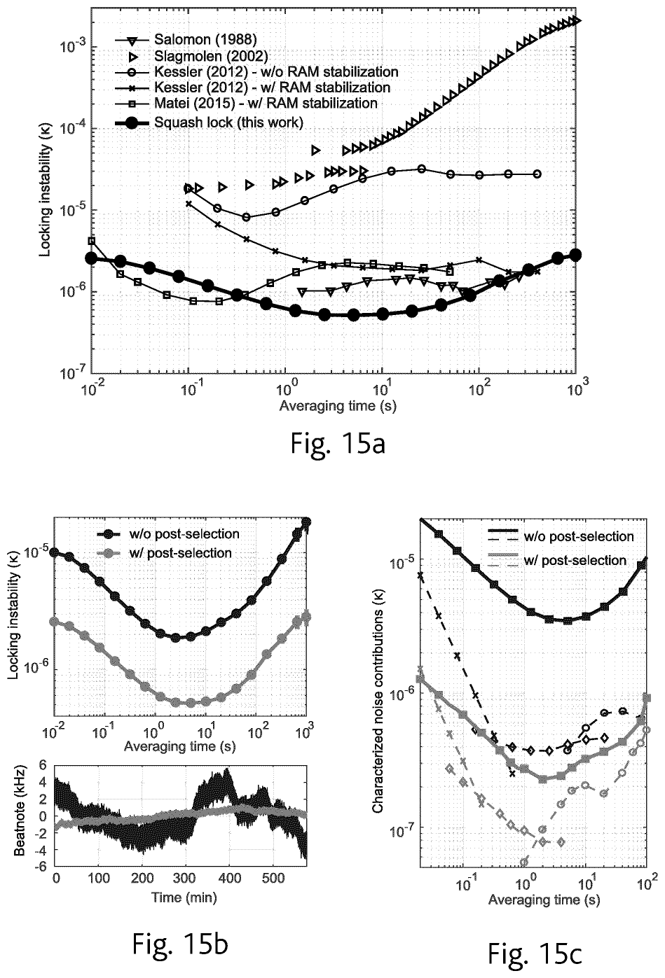

FIG. 15a illustrates the locking instability over averaging time of the experimental setup shown in FIG. 14 in comparison to other stabilization methods.

FIG. 15b shows a comparison of the achieved instability for operation with and without post-selection and at the bottom the corresponding beatnote time traces.

FIG. 15c shows estimated limitations to stability.

FIG. 1 shows a beam ellipticity detection of an incident signal 1 using a detector 2 and the mode decomposition of a slightly elliptical beam. The detector 2 is a quadrant photodiode (QPD) 3 with four sensor regions 4. The quadrant photodiode 3 produces electrical currents proportional to the input light from each of four sensor regions 4. Deriving the error signal 9 (not shown in FIG. 1, see FIG. 2) includes determining a diagonal signal of the quadrant photodiode 3, which diagonal signal is made up of the difference of the sums of signals from diagonal sensor regions 4 of the quadrant photodiode 3. The signal from each of the sensor regions 4 is labelled A, B, C and D, wherein on the quadrant photodiode 3, the sensor regions 4 are arranged in the order A, D, B, C (e.g. in clockwise direction). This allows the following operation: SUM=A+B+C+D, LR=(A+C)−(B+D), UD=(A+D)−(C+B), and DIAG=(A+B)−(C+D). The beam ellipticity (or a parameter directly proportional to the beam ellipticity; depending on the rotational alignment of the detector and the cavities determining the relevant modes) can be measured using the DIAG operation, as can be seen in FIG. 2. A zero DIAG signal indicates the lack of beam ellipticity, meaning the geometric beam shape of the incident signal 1 is circular. A non-zero DIAG signal indicates the presence of an elliptic incident signal 1 on the quadrant photodiode 3. Opposite signs of the DIAG signal indicate opposite ellipticities. The quadrant photodiode 3 can be an InGaAs-based or a silicon-based detector. The signals are further converted into voltages. Further, the error signal 9 is generated with a transimpedance filter (AMP) 5, e.g. using standard analog electronics with operational amplifiers, and a controller 6 (not shown in FIG. 1). The incident angle or incident angles P 7 and Y 8 of the incident optical signal 1 onto the detector 2 can be varied by tilting either the detector 2 with respect to the optical axis of the incident signal 1, or by tilting the optical axis of the incident signal 1 with respect to the main extension plane of the detector 2 (e.g., by tilting a mirror upstream of the quadrant photodiode 3). The relative change of the geometric beam shape of the incident signal 1 is most pronounced at the resonance of the laser with the optical seed signal 10 (not shown in FIG. 1, see FIG. 3).

Therefore, the method is most sensitive at the transmission peak of the incident signal 1, which is also a transmission peak of the optical seed signal 10. The distance between the laser 11 and the detector 2 influences the Gouy phase between the TEM₀₀ mode and the second order spatial modes. The resulting image on the detector 2 can therefore be tuned by adjusting the location of the detector 2 relative to the laser 11. The positions of the detector 2 and the laser 11 are fixed during calibration and remain constant during operation. There are axial distances at which the error signal 9 is purely dispersive and other axial distances at which the error signal 9 is purely absorptive or any signal shape in between absorptive and dispersive.

FIG. 2 illustrates a frequency dependence of an error signal 9 for an optical seed signal 10 (not shown in FIG. 2) near the ‘00’ mode resonance of the laser 11 (not shown in FIG. 2), whereas the DIAG signal is used as the error signal 9. This error signal 9 is dispersive. Note that in this case the native output of the laser 11 has a circular geometric beam shape and the optical seed signal 10 also has a circular beam shape. The error signal 9 comprises a zero-crossing at zero detuning of the laser 11 relative to the optical seed signal 10. This also corresponds to a substantially circular incident signal 1 on the detector 2. Depending on the detuning, the geometric shape of the incident signal 1 changes from circular to elliptic, leading to a non-zero error signal 9. The sign of the error signal 9 shows the orientation of an elliptic incident signal 1. At zero detuning, the transmission 12 of the incident signal 1 through the cavity of the laser 11 has a peak. The zero-crossing of the error signal 9 lies in an interval between a global minimum 13 and a global maximum 14 of the error signal 9. The interval comprises an error signal 9 value corresponding to a determined ellipticity of the incident signal 1. The incident signal 1 acquires opposite ellipticities on opposite sides of the peak of the transmission 12. This is utilized to determine the error signal 9, which is further used for controlling the laser 11 and thus stabilizing the laser output signal 15. The incident signal 1 can be thought of as an interference between the resonating ‘00’ mode that leaks out of the laser 11, and the second-order ‘+’ mode that promptly reflects from the laser 11 to form a phase reference. Due to this detection modality, the error signal 9 is insensitive to alignment drifts and fluctuations, since small misalignments generate (essentially only) first-order modes in the mode decomposition of the incident signal 1. Due to the slope of the error-signal 9, the error signal 9 is used to control the laser 11 to achieve locking of the laser to the optical seed signal 10.

FIG. 3 shows a closed loop control system 16 for controlling an injection-locked laser 11 with an external optical seed signal 10. The laser 11 is a semiconductor laser 17 and produces an optical output signal 15. An optical isolator 18 with a seed injection port 19 is used, through which the external optical seed signal 10 is injected in the laser 11. The frequency of the injected optical seed signal 10 is at or near resonance of the laser 11. The optical isolator 18 prevents the optical output signal 15 from the laser 11 from being re-injected into the laser 11. The system includes an optical component 20 for propagating at least a portion of the output signal 15 from the laser 11 as an incident signal 1 onto the detector 2. The optical component 20 is a beam splitter 21, which is used to split the output signal 15. The reflected portion at the beam splitter 21 is further directed towards the detector 2 and is used as the incident signal 1, which is propagated onto the detector 2. The axial distance between the laser 11 and the detector 2 is such that a transmission 12 peak of the incident signal 1 matches a zero-crossing of the error signal 9.

The beam splitter 21 can for example reflect less than 1% of the incoming intensity. The detector 2 is inclined with respect to the optical axis of the incident signal 1. The detector 2 is a QPD 3, as explained in connection with FIG. 1. A controller 6 is configured to receive signals from the sensor regions 4 of the QPD 3 to derive an error signal 9 based on a geometric beam shape, in this case based on the ellipticity. Deriving the error signal 9 includes applying an offset to the error signal 9 in a way that the error signal 9 at the setpoint is zero. The setpoint is determined by the target state of the laser cavity 22 of the laser 11. For example, the target state is achieved when the optical seed signal 10 is perfectly mode matched to the TEM₀₀ laser mode and/or the central frequency of the optical seed signal 10 is in resonance with the laser. The controller 6 is configured to control one or more operation parameters of the laser 11 based on the error signal 9 to stabilize the laser 11 to the setpoint.

Operation parameters of the laser 11 with a laser cavity 22 include:
temperature of a laser cavity 22,
path length of the laser cavity 22,
pumping of the laser cavity 22,
phase of the optical seed signal 10.

The system 16 can also be used for continuously shifting the wavelength of the output signal of the injection-locked laser 11 by shifting the wavelength of the optical seed signal 10. The adjustment of the wavelength of the optical seed signal 10 causes a change of the error signal 9. The change in the error signal 9 causes the controller 6 to control at least one operation parameter of the laser 11 to restore the relation between the laser 11 and the optical seed signal 10, in other words to reach the setpoint. Thus, by shifting the wavelength of the optical seed signal 10, the wavelength of the optical output of the laser 11 can be shifted due to the tracing effected by the closed control loop.

The laser 11, the beam splitter 21 and the detector 2 can be integrated on a common micro-optics or silicon photonics platform (not shown in the figures).

The closed loop control system 16 performs a method for monitoring the optical signal 15 extracted from an optical cavity 42 (see for example FIG. 7), in this embodiment the laser cavity 22, comprising the steps:
receiving at least a portion of the optical signal 15 as an incident signal 1;
converting the incident signal 1 into the error signal 9 (see FIG. 2) by applying a conversion configuration including:
   propagating the incident signal 1 onto the detector 2 and
   deriving the error signal 9 based on a geometric beam shape (see FIG. 1 and FIG. 2), in particular based on a beam shape ellipticity, for example as proportional to a beam shape ellipticity, of the propagated incident signal 1 on the detector 2;
wherein the error signal 9 has a local minimum, in particular a global minimum 13 (see FIG. 2), and a local maximum, in particular a global maximum 14 (see FIG. 2),
wherein the local minimum and the local maximum delimit an interval 59 of error signal values (see FIG. 2 or FIG. 10 for example),
wherein the conversion configuration configures the interval 59 to comprise a zero-crossing 58 (see FIG. 10) of the error signal 9 when the optical cavity 42 is in the target state.

FIG. 4 shows another closed loop control system 16 for controlling a self-injection-locked laser 11, using a portion of the output signal 15 of the laser 11 to inject it back into the laser 11. Compared to the setup of FIG. 3, a second beam splitter 23 is used to propagate a portion of the output signal 15 of the laser 11 to a frequency selective back-reflector 24. The optical isolator 18 is omitted. The second beam splitter 23 can have any splitting ration, in particular a splitting ratio of 50/50 is beneficial in the shown setup. The frequency selective back-reflector 24 can be any optical element that reflects back at least a fraction the laser power into the laser 11, thus effecting self-injection. It can for example be a mirror (in which case it may not be frequency selective), an optical grating, a resonant optical cavity or any optical element that reflects back at least a portion of incoming optical power. Preferably the back-reflector 24 reflects back a certain wavelength of light, to achieve a narrow linewidth of the optical seed signal 10 and consequently a narrowing of the output signal 15 of the laser 11. In this embodiment, it is beneficial to have an imposed angle 7,8 of the detector different to 0° of the optical axis of the incident signal 1 relative to a normal vector of the main extension plane of the active area of the detector 2. This minimizes reflection from the detector surface from circulating back into the laser 11. In addition, the imposed angle 7,8 can be used to tune the error signal 9 during calibrating the system 16. Alternatively, the detector surface may be used as back-reflector 24 for self-injection and a different parameter than the imposed angle may be used for calibrating the error signal 9.

FIG. 5 shows another embodiment of the closed loop control system 16 for controlling a self-injection-locked laser 11. The optical seed signal 10 is generated by propagating a portion of the output signal 15 of the laser 11 through an optical cavity 25, which serves as a back-reflector 24. The spectral transmission of the optical cavity 25 depends on the optical path length of the optical cavity 25. Thus, by controlling the optical path length of the optical cavity 25, the optical seed signal 10 can be controlled and thus the output signal 15 of the laser 11 can be shifted.

The laser 11 has an output signal 15, which is split by a beam splitter 21. The transmitted portion is in this embodiment further shaped by a lens 39 and propagated through optical isolators 26. The beam splitter 21 reflects a portion of the output signal 15. By means of a mirror 27 and piezo-mounted mirror 28, the fraction of the output signal 15 is propagated to the optical cavity 25. Before the optical cavity 25, a lens 29 is used to mode match the optical output signal 15 to the optical cavity 25, which optical cavity 25 is formed by a second beam splitter 30, a second mirror 31 and second piezo-mounted mirror 32. The second piezo mounted mirror 32 is used to determine the spectral transmission through the optical cavity 25. The optical cavity 25 is configured in a way that the reflected intensity at the second beam splitter 30 is propagated to a detection lens 33 and onto the detector 2, which is a QPD 3. The detection lens 33 is a convex spherical lens 34.

The transmitted intensity through the second beam splitter 30 and through the optical cavity is reflected back towards the laser 11 and therefore provides the optical seed signal 10 for self-injecting the laser 11.

The controller 6 (not shown in FIG. 5; see FIG. 3) derives the error signal 9 and controls one or more of the operation parameters of the laser 11 responsive to the error signal 9. These parameters include:
temperature of the laser cavity 22,
   path length of the laser cavity 22,
   pumping of the laser cavity 22,
   phase of the optical seed signal 10.

The phase and the injection of the optical seed signal 10 can be manipulated by the piezo controlled mirror 28.

In this example, the laser 11 is a standard Eagleyard DFB 780 nm 100 mW laser. The external optical cavity 25 assembly is formed by three mirrors: concave [r=10 cm], plane, concave. The cavity has a linewidth of 10 MHz. The L-shape of the optical cavity 25 allows easy mode-matching and access to the reflected beam as an incident signal 1 on the detector 2. However, many different cavity geometries can be used including a confocal 2-mirror cavity, as long as the promptly reflected beam is not reflected directly back into the laser—only the intra-cavity circulating light is to be self-injected into the laser.

FIG. 6 shows another embodiment of the closed loop control system 16 for controlling a self-injection-locked laser 11. Compared to the embodiment of FIG. 5, a third beam splitter 35 is used and a second detector 36 is configured to receive a second incident signal 37 transmitted through the third beam splitter 35. The second detector 36 is a QPD. The embodiment of FIG. 6 is a combination of the embodiments of FIGS. 4 and 5.

The addition of the second detector 36 leads to a second error signal 38 (not shown but similar to error signal 9, details see FIGS. 1 and 2) that is used to monitor the injection status of the laser 11 (as in the embodiment of FIG. 4), the resulting error signal 38 is specifically used by the controller 6 (not shown in FIG. 6; see FIG. 3) to control one or more of the following operation parameters of the laser 11:
temperature of the laser cavity 22,
   path length of the laser cavity 22,
   pumping of the laser cavity 22.

In this embodiment, the error signal 9 of the detector 2 is used by the controller 6 to stabilize the phase of the optical seed signal 10. The incident signals on the detectors 2 and 36 can be understood as an interference between the resonating TEM₀₀ mode of an optical cavity, such as the laser cavity, and the second-order ‘+’ mode that promptly reflects from the optical cavity to form a phase reference. In the case of the detector 2, the signal is based on an interference of the TEM₀₀ mode of the optical cavity 25 with the output signal 15 of the laser 11.

The signal at the second detector 36 however, is based on an interference of the TEM₀₀ mode of the laser cavity 22 with the transmitted signal through the optical cavity 25, which is back-reflected to the laser 11 to serve as the optical seed signal 10 and reflected from the laser cavity 22 to form a phase reference. It is therefore beneficial to use the error signal 9 based on the signal on the (first) detector 2 to adjust the phase between the laser cavity 22 and the optical cavity 25 (which is also the phase of the optical seed signal) by means of the piezo-mounted mirror 28 and to use the second error signal 38 based on the signal at the second detector 36 to control one or more of the remaining operation parameters of the laser 11. The use of two detectors 2 and 36 in this embodiment yields a more stable setup as more information on the injection locking is available and used for controlling the operation parameters.

FIG. 7. schematically shows an embodiment of the device 40 for frequency locking a laser 41 to an optical cavity 42. In this embodiment, the device 40 comprises the laser 41 and the optical cavity 42 is formed as a three-mirror optical cavity. A laser beam from the laser 42 is coupled into a polarizing fibre 43 at input collimator 44. The optical fibre 43 comprises a 50:50 polarization maintaining fiber splitter 45, wherein one of the outputs of the fiber splitter 45 may be used as the “useful” light. Further, there is provided for a polarizing fiber (PZF) 46 and a fiber collimator 47 for emitting the laser beam from the polarizing fiber 43. The emitted laser beam is directed at the beam shaper 48 for shaping the laser beam such that the laser beam acquires ellipticity. In this embodiment, the beam shaper 48 comprises a pair of cylindrical lenses (CLP) 49, which have focusing axes oriented perpendicularly to each other. Subsequently, the laser beam is subjected to a first polarizing beam splitter (PBS) 50, which is rotatable.

The laser beam is subsequently directed at the cavity input mirror 51 of the optical cavity 42. The laser beam reflected from the optical cavity 42 is directed at the detection lens (DL) 52, which may be a (e.g. 100 mm) convex spherical lens. The detection lens 52 is for focusing the laser beam reflected from the optical cavity 42. Subsequently, the laser beam passes a second polarizing beam splitter 53. The device 40 further comprises a detector 54 for determining an error signal proportional to a beam ellipticity of the laser beam focused by the detection lens 52. In this embodiment, the detector 54 is a quadrant photodiode 55, wherein the detector 54 is configured to determine the error signal based on a diagonal signal of the quadrant photodiode 55, which diagonal signal is made up of the difference of the sums of signals from diagonal sensor regions of the quadrant photodiode 55.

The device 40 according to the embodiment shown in FIG. 7 performs the method for monitoring the optical signal 15 extracted from the optical cavity 42. In this case the optical signal 15 is the laser beam reflected from the optical cavity 42. The method comprises the steps:
receiving at least a portion of the optical signal 15 as an incident signal 1 (in this case the signal that is incident on the quadrant photodiode 55);
converting the incident signal 1 into the error signal 9 (see FIG. 10) by applying a conversion configuration including:
   propagating the incident signal 1 onto the detector 2 (in this case the quadrant photodiode 55) and
   deriving the error signal 9 based on a geometric beam shape (see FIG. 8C), in particular based on a beam shape ellipticity, for example as proportional to a beam shape ellipticity, of the propagated incident signal 1 on the detector 2;
wherein the error signal 9 has a local minimum, in particular a global minimum 13 (see FIG. 2 or FIG. 10), and a local maximum, in particular a global maximum 14 (see FIG. 2 or FIG. 10),
wherein the local minimum and the local maximum delimit an interval 59 of error signal values (see FIG. 10 for example),
wherein the conversion configuration configures the interval 59 to comprise a zero-crossing 58 (see FIG. 10) of the error signal 9 when the optical cavity 42 is in the target state. The target state refers in this case to an optimal frequency locking of the laser 41 to the optical cavity 42.

FIGS. 8a, 8b and 8c conceptually illustrate the error signal generation based on which the laser can be locked (indicated by the dotted line in FIG. 7 indicating the use of the error signal as feedback for locking the laser, e.g. by adjusting the laser current).

FIG. 8a schematically shows a triangular ring cavity geometry and its relevant Hermite-Gaussian mode resonances. In this embodiment, the optical cavity 42 comprises two plane mirrors and one (e.g. 5 cm radius-of-curvature) convex mirror. Further, the spatial amplitude structure of the ‘00’ and the ‘+’ modes are illustrated in the inset. In terms of the native cavity modes, the ‘+’ mode appears as a superposition of the ‘02’ and ‘20’ modes. Alignment drifts populate the ‘01’ and ‘10’ modes. Therein, v_{FSR} represents the free spectral range and n represents an integer. In this example, the cavity parameters may be: 7.01 cm round trip length, v_{FSR}=4.28 GHz, finesse of 195 for the ‘00’ mode.

FIG. 8b illustrates the beam ellipticity detection using a quadrant photodiode and the mode decomposition of a slightly elliptical beam, wherein F is a small complex number. As can be seen from FIG. 8b, the DIAG=(A+B)−(C+D) function of the quadrant photodiode 55 gives the beam ellipticity. Further, the error signal is generated with a transimpedance filter (AMP).

FIG. 8c illustrates the frequency dependence of the error signal for light reflected from the cavity near the ‘00’ mode resonance, wherein x is the cavity full-linewidth.

The positioning of the detection lens 52 and the detector 54 will subsequently be explained in the context of FIGS. 9 and 11.

FIG. 9 illustrates the location of the relevant elements in the laser beam path and the resulting beam properties, in particular beam waists in-plane and out-of-plane and the resonator mode beam waist, in the embodiment of FIG. 7. In particular, a configuration of the optical elements that excite the TEM₀₂ and TEM₂₀ modes at about 5% relative to the peak power of the TEM₀₀ mode is shown. Prior to reaching the beam shaper 48 with the pair of cylindrical lenses 49, the laser beam's beam waists in-plane and out-of-plane match. As can be seen, the beam shaper 48 imposes an ellipticity on the laser beam. At the detection lens 52, the laser beam is focused. The detector 54 is shown in the position were the in-plane and out of plane beam waists match the resonator mode beam waist. The mean cavity mode waist may be at 74 μm, the in-plane beam waist at 84 μm and the out-of-plane beam waist at 65 μm. Further, the tuning interval 56 is shown, within which the axial distance 57 of the detector lens 52 and the detector 54 can be adjusted in order to use the error signal for frequency locking the laser. The dimensions in the figures (e.g. of the position in cm in FIG. 9) are only chosen for illustrational purposes and may also take on different values.

FIG. 10 illustrates the error signal and cavity transmission in the embodiment of FIG. 7. The axial distance 57 is adjusted such a zero-crossing 58 of the error signal lies within an interval 59 between a minimum 60 and a maximum 61 of the error signal, such that an error signal value corresponding to a determined beam ellipticity of a substantially circular laser beam—when the laser provides a laser beam at the resonance frequency of the cavity—is within the interval 59. The interval 59 in terms of the frequency translated into the tuning interval 56 of the axial distance 57. The error signal shown in FIG. 10 can be used to lock the laser 41 to the optical cavity 42.

A second laser system could also be locked on the opposite side of the optical cavity 42, mirror the left side. In principle, with this three-mirror cavity, up to three lasers can be locked simultaneously. This can be scaled up by increasing the mirror count. Alternatively if the laser wavelengths are sufficiently different, multiple lasers can be locked using the same input mirror, provided the beams for each wavelength are separated with filters afterwards.

FIG. 11 illustrates the error signal and the transmission. Even though the background offset is zero or minimized when the in-plane and out-of-plane beam waists match exactly with the cavity mode beam waist, the error signal's zero crossing 58 does not exactly correspond to the plateau of the transmission peak of the optical cavity 42, as can be seen in FIG. 11. Therefore, it is even further preferred if the axial distance 57 of the detection lens 52 and the detector 54 is adjusted such that the transmission peak of the laser beam reflected from the optical cavity 42 matches a zero crossing 58 of the error signal. FIG. 11 shows the error signal with the beam waists matched (“initial”) and with the transmission peak and the zero-crossing 58 matched (“optimized”).

FIG. 12 schematically illustrates the axial distance 57 between the detection lens 52 and the detector 57. The laser beam can also be centered on the detector 57. This is achieved by translating the detection lens 52 (and/or the detector 54) in the directions 62 (“LR”, i.e. left-right, and “UD”, i.e. up-down) perpendicular to the optical axis 63 such that a left-right signal and an up-down signal of the quadrant photodiode 55 are minimized. The left-right signal LR=(A+C)−(B+D) and the up-down signal UD=(A+D)−(C+B) are each made up of the difference of the sums of adjacent sensor regions of the quadrant photodiode 55, wherein the left-right signal and the up-down signal use the sums of different halves of adjacent sensor regions. It is preferable, if the laser beam is re-centered when the axial distance 57 is adjusted. Therefore, it is preferable if these steps are conducted repeatable and iteratively. I.e., for every adjustment of the axial distance 57, the LR and UD signals should be minimized again. By repeating this process, the zero crossing 58 is optimized to match exactly the transmission plateau, as is shown for the “optimized” error signal in FIG. 11.

FIGS. 13a to 13c illustrate the weak value enhancement, i.e. the effective cavity under polarization pre- and post-selection. In particular, FIG. 13a illustrates the use of a first and a second polarizers in the embodiments of FIG. 7 and of FIG. 14 described below. An input polarizer 11 and an output polarizer 53 is used to obtain the weak-value r_{W} of the reflection operator ?, resulting in an effective cavity with a tunable reflection. The polarizers 50, 53 are both linear polarizers. Thus, the laser beam is polarization filtered prior to being directed at the optical cavity 42 and the laser beam reflected from the optical cavity is also polarization filtered. FIG. 13b illustrates the measured normalized reflection power for different post-selection configurations. Curves are labelled by their off-resonant remaining power fraction | [symbol] 2|ψ1 [symbol] |². The ½-curve is the same as the original cavity reflection curve; the 1/60 curve is the impedance matched (γ′=1) configuration. The dash-dot lines represent intensity contribution levels from the non-‘00’-mode components. FIG. 13c shows the real and imaginary part of R_{W} for an input mode matched to the ‘00’ mode (in theory), illustrating the advantages of post-selection: An effective increase in the slope of the error signal and a minimization of optical power on the detector 54 near the locking point is achieved. FIG. 14 illustrates two copies of the lockup setup, which was used to demonstrate the performance of the stabilization scheme. The two copies share the same optical cavity 42 and apart from that each comprises (on its own) the same elements as the device 40 described in the context of FIG. 7. Therefore, reference is made to the description of FIG. 7 and the same elements are indicated by the same reference numerals. Two separate lasers 41 were stabilized to two degenerate counter-propagating ‘00’ modes of the triangular ring cavity 42.

The distance between the pair of cylindrical lenses 49 determines the amount of light in the ‘+’ mode, which amounts to around 10% of the total power (about 400 μW) used in the experiment.

A comparison between different optical frequency stabilization systems can be achieved by characterizing the performance as a fractional instability with respect to the cavity linewidth—nominally, absolute instabilities will scale proportional to the cavity linewidth since typical sources of problematic instabilities originate from fluctuations in the error signal shape. In this experiment, a 22-MHz full-linewidth cavity was employed and two external cavity diode lasers at 780 nm with 500 kHz intrinsic-linewidths.

FIG. 15a illustrates the locking instability over averaging time of the experimental setup shown in FIG. 14 in comparison to other stabilization methods. The performance of the implemented scheme while locked to a ‘00’ mode resonance is shown. The 10⁻⁷ locking instability regime is reached for averaging times between 0.25 s and 100 s, surpassing previous state-of-the-art, and reaching 5×10⁻⁷ instability at 10 s averaging time. The Allan deviation of a 10-hour recorded beatnote is taken and equal instabilities for the two locks are assumed. The comparison is conducted with respect to the following methods:
Salomon (Salomon, C., Hils, D. & Hall, J. L. Laser stabilization at the millihertz level. J. Opt. Soc. Am. B 5, 1576 (1988).): transmission modulation method;
Slagmolen (Slagmolen, B. J. J., Shaddock, D. A., Gray, M. B. & McClelland, D. E. Frequency stability of spatial mode interference (tilt) locking. IEEE J. Quantum Electron. 38, 1521-1528 (2002).): double-passed ‘tilt locking’ method;
Matei (Matei, D. G. et al. 1.5 m Lasers with Sub-10 mHz Linewidth. Phys. Rev. Lett. 118, 263202 (2017).): PDH method;
Kessler (Kessler, T. et al. A sub-40-mHz-linewidth laser based on a silicon single-crystal optical cavity. Nat. Photonics 6, 687-692 (2012).): PDH method out-of-loop noise floor characterization with and without RAM stabilization (arXiv:1112.3854 for this data). Data were extracted and expressed relative to cavity linewidths utilized in each work.

FIG. 15b shows at the top a comparison of the achieved instability for operation with and without post-selection and at the bottom the corresponding beatnote traces.

FIG. 15c shows estimated limitations to stability of an operation with post-selection, an operation without post-selection, with the dominant contribution due to beam shape noise in solid lines and the subdominant contribution in dashed lines. The break-down of the subdominant contributions is as follows: measured in-loop error signal noise (crosses), detector 54 dark noise (diamonds) and laser 41 intensity drift noise (circles).

The experiment conducted with the setup shown in FIG. 14 is now described in more detail. It is noted, however, that different parameters may be used as well and this should not be considered limiting to the invention.

The optical cavity 42 is made of one high reflectivity curved mirror (5 cm radius of curvature) and two lower reflectivity (−98.93 for p-polarization at 30° angle of incidence) plane mirrors. The reflectivities are chosen to make the cavity linewidth larger than those of the lasers 41 (500 kHz) for simplicity. The mirrors are attached with an epoxy resin on an aluminum block with three drilled bores that form a nearly equilateral triangle. The fiber collimator 47 and pair of cylindrical lenses 49 forming the beam shaper 48 are mounted on a cage assembly, which is situated on a 5-axis tip-tilt-translation stage. This assembly, together with the axial translation capability of the fiber collimator lens makes it easy to mode match to the optical cavity 42. The optical cavity 42, together with the remaining optics are all mounted directly onto the optical table, and are enclosed with a metal box for temperature and air fluctuation stability. The aluminum cavity spacer is temperature stabilized to within 1 mK to control the cavity length.

To experimentally identify the cavity mode reference profile (cf. also FIG. 9), light is back coupled to the ‘00’ mode from one of the mirrors and the mode profile emitted out of the cavity 42 (along the path to the quadrant photodiode (QPD) 55) is characterized with a CMOS camera. Incident beam profile is adjusted by tuning the location of the optical elements to match the reference mode upon reflection from the cavity. Once aligned, all other modes but the ‘00’ and the ‘02’-‘20’ are suppressed, with an equal transmission level for the latter two.

Following the input light alignment, the QPD 55 location is aligned. For centering the beam on the QPD 55, the detection lens (DL) 52 is translated while monitoring the left-right and up-down signals from the QPD 55. With the beam centered, a baseline offset on the error signal is attributable to an axial displacement of the QPD 55 location from the location where the beam assumes a circular profile. The QPD 55 location can in principle be adjusted to eliminate this offset. However, the natural astigmatism of the cavity 42 also contributes to the baseline offset. This also gives rise to a shift of the transmission peak from the error signal zero-crossing 58. Hence the axial QPD 55 location can be adjusted until the transmission peak and the error signal zero-crossing 58 matches. In absence of this matching, a cross-coupling of intensity noise to frequency noise emerges.

The electronic backend: The QPD 55 and the feedback circuits are home built. All quadrants of the QPD 55 are independently amplified with a 380 kOhm transimpedance gain, and arithmetic operations are then carried out with operational amplifier circuits to simultaneously access the diagonal, left-right, up-down and sum signals. These respectively give us the cavity lock error signal, the beam centering signals and the total light intensity reflecting from the cavity.

The signal from the diagonal channel goes to an analog feedback circuit and is fed to the laser current to keep the lasers 41 on resonance with the cavity when locked. The feedback loop contains two integrators (1/f² response) from DC to 20 kHz, and a single integrator (1/f response) from 20 kHz to the lock bandwidth of 100 kHz, providing a lock tightness that does not pose a dominant limitation to stability (crosses in FIG. 15c). All input and output signals to the feedback circuits are differential in order to eliminate ground loops, which is crucial to performance.

We note that the QPD 55 together with the implemented amplification circuit operates shot-noise limited for frequencies larger than 300 Hz. Below this frequency amplifier noise starts taking over. However the observed locking stability for timescales larger than 10 ms is not related either to shot noise or to amplifier noise, and this is typical for other experiments operating in such timescales.

System performance, comparison and noise characterization:

Assuming equal performances for the two copies of the laser-cavity locking setup, the actual instability for one of the copies is given by 1/√2 of the measured laser beatnote instability since the independent noises add in quadrature. This correction is already taken into account in FIG. 15, and is a standard procedure. This in general provides a conservative estimate of achievable instability, since if one of the two setups were to perform better, extracting the performance of that setup would require dividing with an even larger number. In our case, the performance of any of the two copies is roughly equal, since the characterized beam shape noise which limits the performance turned out to be the same for both copies.

For comparison with previous state-of-the-art, we extracted instability data from the works cited in FIG. 15 (see below) using WebPlotDigitizer, and scale the data to represent fractions relative to cavity linewidths utilized in each work. In choosing specific publications for comparison, we payed particular attention to works involving more than one similar setup to obtain a real measured stability through a laser beatnote. Note that, one can try to infer a locking stability from a single copy of the system by recording the in-loop error signal and utilizing an appropriate conversion factor. This method is not necessarily reliable since a feedback loop suppresses the error signal irrespective of its physical origin. For example, the in-loop error signal in our work continues to average into the 10⁻⁸ instability scale, but the real stability limitation is brought by the deviation of the error signal from the actual frequency value due to beam shape noise. Among the comparison data, the ‘Slagmolen’ and ‘Salomon’ curves, together with the results presented in this work are obtained by locking two lasers to the same cavity, whereas the ‘Matei’ curve is obtained by comparing two lasers locked to separate cavities—and is limited by the thermal noise of the utilized cavities.

The estimated limitations to stability presented in FIG. 15c (see below) were carried out ex situ. The beam shape noise was measured by physically blocking the cavity mode, so that no light builds up inside the cavity. In this configuration, the input mirror promptly directs the incident light to the QPD and allows one to characterize the beam ellipticity fluctuations in the incident beam. No further modelling was done to take into account any shape noise filtering effects that the cavity might perform while the mode is not blocked. The QPD dark noise was measured by blocking the incident light and monitoring the error signal. The intensity drift noise was measured by simultaneously monitoring the laser beatnote frequency and the sum channels of the QPDs 55 while the lasers 41 were locked to the cavity 42. Except for the intensity noise, the on-resonance error signal slope was used to convert the measurements to frequency. For the intensity drift noise, the measured laser intensity dependence of the beatnote in locked operation was used. We note that there is no active intensity stabilization in this work.

It was verified that the stability limitation indeed comes from beam ellipticity fluctuations and not indirectly from beam pointing fluctuations combined with non-idealities in the QPD detection system. By translating the QPD position perpendicular to the beam axis, a cross-talk isolation between the beam position and beam ellipticity signals in excess of a factor of 200 was observed. On the other hand, the voltage noise in the beam position signals during operation are only one order of magnitude larger than that in the ellipticity signals, ruling out the beam pointing cross-talk as the dominating noise source.

A narrower laser linewidth would in principle improve stability in the short time scales, assuming there are no other dominating sources of defection noise in the system. In our case, artificially broadening the laser linewidth from 500 kHz to 1 MHz (by injecting current noise) did not deteriorate the performance, suggesting that the linewidth is not the limitation. We also note that there is no laser linewidth narrowing induced in our parameter regime, since the lock bandwidth (100 kHz) is smaller than the initial laser linewidth. An advantage of the locking method investigated in this work in comparison to the next-best ‘transmission modulation’ method (FIG. 15a) is its use of the reflected beam—a property also shared with the PDH method. In this mode of operation, lock bandwidth is not directly limited by the cavity linewidth. This is important in the context of narrow linewidth high finesse cavities, when one tries to narrow the linewidth of a laser in addition to stabilizing its central frequency.

As an additional note, the fundamental limits of many frequency locking techniques due to optical shot noise have been shown to be the same to within a numerical factor of order unity, and our method is no exception.

Advantages of post-selection: In addition to the already-discussed suppression of sensitivity to intensity noise and incident beam shape fluctuations, the post-selection reduces sensitivity to beam pointing fluctuations. Although these fluctuations affect the signal in the diagonal QPD channel only to second order, and do not appear to cause a limitation in the current work, they are nevertheless further reduced. Another non-ideality that the post-selection suppresses is an adverse effect of the astigmatism of the triangular cavity modes. The astigmatism causes the zero-crossings of the error signal to become offset from the transmission intensity maxima. This results in reduced performance through intensity-to-frequency noise conversion. One can mitigate this effect by fine tuning alignment as discussed in the alignment procedures, nonetheless, the post-selection significantly suppresses these problems, rendering alignments easier.

Qualitatively, the improvements brought by the post-selection can be thought of as originating from a differential measurement performed on two beams with orthogonal polarizations—one that goes into the cavity and one that is promptly reflected from the cavity. Through post-selection, this differential measurement is manifested as a coherent process which improves the slope of the error signal (making it more sensitive to smaller frequency shifts) for a fixed amount of light impinging on the QPD. The post-selection process improves performance as long as the resulting intensity on the QPD does not fall below an equivalent electronic noise floor.

Alongside all improvements, the post-selection is also observed to introduce a small sensitivity of frequency lock point to cavity length changes. Preliminarily characterizations suggest that this increased sensitivity is likely due to polarization changes in the light reflecting from the cavity as the light frequency changes—effectively changing the post-selection angle. Nevertheless cavity length is a parameter that is necessarily well controlled in frequency stabilization applications, and it does not pose a dominant limitation in our implementation.

Application to different cavity geometries:

In FIGS. 7 and 14, a ring cavity is utilized where the incident and reflected beams are traveling on separate paths. For different applications, different cavity designs might be required. For example, ultralow-vibration sensitivity typically requires working with two-mirror standing wave cavities. For this configuration nothing changes regarding the main method: Although the reflected beam travels on the same path as the incident beam, it can easily be separated, e.g., using a quarter-wave plate together with a polarizing beam splitter (as is usually done for the PDH method). Also note that the specific mode spectrum of a cavity does not play a role in the implementation; the only requirement for proper operation is for the TEM₀₀ mode not to be spectrally degenerate with the second-order modes, and thus the second order modes can have arbitrary generic resonance frequencies. The main method can also be used with waveguide-like cavities which require evanescent coupling, e.g., with dielectric whispering gallery mode cavities, or fiber rings. A well established coupling strategy is the use of a prism, where the evanescent tails from the prism during total internal reflection couple light in-and-out of the cavity. The prism thus effectively interfaces waveguide-like structures into free space optics, and it appears like an input mirror of a free-space cavity for the purposes of applying the methods developed here.

Post selected beam evolution and the weak value of the reflection coefficient:

Here we outline the derivation of the effective reflection coefficient and related formulas used above. First, we model the cavity reflection without the polarization degree of freedom in the quantum mechanical language used for describing weak-values, then we take into account the polarization.

In the first case, there are two degrees of freedom in the problem: the ‘mode shape’ and the ‘channel’. The states spanned by the first are the various TEM modes, and the states spanned by the second are the labels ‘incident’ (| [symbol] [symbol] ), ‘reflected’ (| [symbol] [symbol] ) and ‘transmitted’ (| [symbol] [symbol] ). We take the initial state as a direct product state for the two degrees of freedom: |Ψ [symbol] =|Φ [symbol] ⊗| [symbol] . Here, the state ‘Φ’ stands for an arbitrary input mode shape. To phenomenologically describe reflection from the cavity near the ‘00’ resonance, we define a unitary operator Û=|0 [symbol] [symbol] 0|⊗Û_{C}+(i−|0 [symbol] [symbol] 0|)⊗(| [symbol] [symbol] [symbol] |+| [symbol] [symbol] [symbol] |) which evolves the state of the ‘channel’ with another unitary operator U_{C} if the ‘mode shape’ is in state 10), and evolves the incident state | [symbol] [symbol] directly into the reflected state | [symbol] [symbol] otherwise. Here Î is the identity operator for the ‘mode shape’ degree of freedom, and |0 [symbol] [symbol] 0| is the projection operator for the ‘00’ mode. If we are only interested in the reflected part of the beam, an effective evolution operator \hat{R} that acts only on the input ‘mode shape’ state |Φ [symbol] can be defined using a projection onto the reflected part after the state evolution: \hat{R}|Φ [symbol] = [symbol] [symbol] |Û|Φ [symbol] . This procedure yields the effective evolution operator \hat{R}=r|0 [symbol] [symbol] 0|+(I−|0 [symbol] [symbol] 0|) with r+ [symbol] [symbol] |U_{C}| [symbol] [symbol] being the amplitude reflection coefficient—an experimentally determined quantity.

Now, inclusion of the polarization degree of freedom introduces a more general unitary operator that evolves the initial state |Ψ [symbol] =|ψ₁ [symbol] ⊗|Φ [symbol] ⊗| [symbol] [symbol] . Here |ψ₁ [symbol] is the initial state of the polarization degree of freedom. Using the above procedure, an effective evolution operator \hat{R}=\hat{R}_{H}+\hat{R}_{V} acting only on the initial ‘mode shape’ and ‘polarization’ state |ψ₁ [symbol] ⊗|Φ [symbol] can be deduced, yielding \hat{R}_{H}=|H [symbol] [symbol] |⊗(r_{H}|0 [symbol] [symbol] 0|+(I−|0 [symbol] [symbol] 0|)) and \hat{R}ᵥ=|V [symbol] [symbol] V|⊗e^{iΦ}(rᵥ|0 [symbol] [symbol] 0|+(I−|0 [symbol] [symbol] 0|)). In these expressions, r_{H} and r_{V} are the amplitude reflection coefficients for the horizontal |H [symbol] and vertical |V [symbol] polarization states—corresponding to the principal axes of the cavity. Here, a potential relative birefringent phase shift Φ is explicitly included for the prompt reflection from an angled cavity input mirror. A further projection onto the polarization state |ψ′₂ [symbol] using the definition \hat{R}ₚₒₛₜ|Φ [symbol] = [symbol] ψ′₂|\hat{R}|Φ [symbol] |ψ₁, yields the final post-selected evolution operator \hat{R}ₚₒₛₜ= [symbol] ψ₂|ψ₁ [symbol] [r_{w}|0 [symbol] [symbol] 0|+(I−0 [symbol] [symbol] 0|)], which acts purely on the input mode state |Φ [symbol] . Here, r_{w}= [symbol] ψ₂|\hat{r}|ψ₁ [symbol] / [symbol] ψ₂|ψ₁ [symbol] is the weak-value of the reflection operator \hat{r}=r_{H}|H [symbol] [symbol] H|+r_{V}|V [symbol] [symbol] V|, and the overlap coefficient [symbol] ψ₂|ψ₁ [symbol] in \hat{R}ₚₒₛₜ further signifies the lossy nature of the post-selection operation. Note that for clarity, we have absorbed the effect of the birefringent phase shift into the definition of the post-selected state: |ψ₂ [symbol] =(|H [symbol] [symbol] H|+|V [symbol] [symbol] |V|e^{-iΦ})|ψ′₂ [symbol] . Above, the small birefringent phase is ignored, but the residual asymmetry of the curves in FIG. 15b can be attributed to it.

Now we will evaluate r, for our experimental configuration. With the use of linear polarizers, the pre- and post-selected states can be written as |ψ₁ [symbol] =cos θ₁|H [symbol] +sin θ₁|V [symbol] and |ψ₂ [symbol] =cos θ₂|H [symbol] +e^{-iϕ}sin θ₂|V [symbol] . This results into r_{w}=r_{H}(½+B)+r_{V}(½−B) for the weak- value, and [symbol] ψ₂|ψ₁ [symbol] =cos(θ₂+θ₁)/(B+½+e^{-iϕ}(B−½)) for the overlap coefficient. Here we defined the complex number B=(1+e^{-iΦ} tan θ₂ tan θ₁)⁻¹−½. For the present work the cavity is polarization resolving, and we can take the vertical polarization component to be far off-resonance, and use

$${r}_{H} = 1 - γ / ( 1 - {i}^{\frac{δ}{κ / 2}} )$$

and r_{V}=1 with γ, δ and κ as defined in the main text. This results into the weak value

$${r}_{w} = 1 - γ ( B + 1 / 2 ) / ( 1 - {i}^{\frac{δ}{κ / 2}} ) .$$

Lastly, we will make the small-birefringent-phase approximation Φ<<1 and expand in a power series in Φ to reach the formulas used in the main text.

We obtain

$${r}_{w} = 1 - {γ}^{′} \frac{1}{1 - i \frac{δ}{κ / 2}} \qquad ( 2 )$$

$$〈 {ψ}_{f} \vert {ψ}_{i} 〉 = {e}^{- i ϕ ( A - 1 )} ( \frac{1}{2 A - 1} + \frac{A ( A - 1 )}{2 A - 1} \frac{{ϕ}^{2}}{2} ) cos ( {θ}_{2} + {θ}_{1} ) \qquad ( 3 )$$

where γ′=Aγe^{-iΦ(A-1)} and A=½+B|_{Φ=0}. The successful post-selection probability can be written as

$${\vert 〈 {ψ}_{f} \vert {ψ}_{i} 〉 \vert}^{2} \approx \frac{1}{{( 2 A - 1 )}^{2}} + \frac{A ( A - 1 )}{{( 2 A - 1 )}^{2}} {ϕ}^{2} ,$$

where we assumed cos(θ₂+θ₁)²˜1 for the relevant post-selection angles. The expressions used above further set Φ=0.

1.-18. (canceled)

19. A method for monitoring an optical signal extracted from an optical cavity, the method comprising:
receiving at least a portion of the optical signal as an incident signal;
converting the incident signal into an error signal, wherein converting the incident signal into an error signal comprises:
propagating the incident signal onto a detector; and
deriving, at the detector, the error signal based on a geometric beam shape of the propagated incident signal on the detector;
wherein the error signal has a local minimum and a local maximum,
wherein the local minimum and the local maximum delimit an interval of error signal values, and
wherein the conversion configuration configures the interval to comprise a zero-crossing of the error signal when the optical cavity is in a target state.

20. The method of claim 19, wherein the conversion configuration configures the interval to comprise an error signal value that corresponds to a substantially circular image of the propagated incident signal on the detector.

21. The method of claim 19, wherein the detector is a quadrant photodiode and wherein deriving the error signal includes determining a diagonal signal of the quadrant photodiode, which diagonal signal is made up of the difference of the sums of signals from diagonal sensor regions of the quadrant photodiode.

22. The method of claim 21, further comprising centering the incident signal on the quadrant photodiode such that at least one of a left-right signal or an up-down signal of the quadrant photodiode is minimized, wherein the left-right signal and the up-down signal are each made up of the difference of the respective sums of adjacent sensor regions of the quadrant photodiode, wherein the left-right signal and the up-down signal use the sums of different halves of adjacent sensor regions.

23. The method of claim 19, wherein propagating the incident signal includes adjusting an incident angle of the incident signal onto the detector.

24. The method of claim 19, wherein propagating the incident signal includes shaping the incident signal with a shaping lens.

25. The method of claim 19, wherein deriving the error signal includes applying an offset to the error signal to set the error signal to zero when the optical cavity is in the target state.

26. The method of claim 19, wherein propagating the incident signal includes focusing the incident signal onto the detector with a detection lens, wherein the detection lens comprises a convex spherical lens.

27. The method of claim 26, wherein propagating the incident beam includes adjusting an axial distance between the detection lens and the detector such that a transmission peak of the incident signal matches a zero-crossing of the error signal.

28. The method of claim 27, wherein adjusting the axial distance of the detection lens and the detector comprises adjusting the axial distance such that an in-plane incident signal waist and an out-of-plane incident signal waist of the incident signal match with a beam waist of a resonance cavity mode of the optical cavity.

29. The method of claim 26, further comprising performing frequency locking of a laser to the optical cavity, wherein performing the frequency locking comprises:
providing a laser beam from the laser;
shaping the laser beam such that the laser beam acquires ellipticity;
directing the laser beam at the optical cavity, wherein the laser beam reflected from the optical cavity is the incident signal propagated onto the detector; and
locking the laser to the optical cavity based on the error signal.

30. The method of claim 29, wherein shaping the laser beam such that the laser beam acquires ellipticity is effected by a pair of cylindrical lenses, wherein the pair of cylindrical lenses have focusing axes oriented non-parallelly to each other.

31. The method of claim 29, wherein the laser beam is polarization filtered prior to directing the laser beam at the optical cavity and the incident signal is polarization filtered.

32. The method of claim 29, wherein the laser comprises a semiconductor laser.

33. The method of claim 19, further comprising: adjusting the optical cavity to reach the target state by minimizing the error signal.

34. The method of claim 33, wherein adjusting the optical cavity includes at least one of adjusting the temperature of the optical cavity or adjusting the path length of the optical cavity.

35. The method of claim 19, wherein the optical cavity comprises a laser cavity.

36. The method of claim 19, wherein the error signal is based on a beam shape ellipticity.

37. The method of claim 31, wherein the error signal is derived to be proportional to the beam shape ellipticity.

38. A system comprising:
means for receiving at least a portion of the optical signal as an incident signal; and
means for converting the incident signal into an error signal, wherein converting the incident signal into an error signal comprises:
propagating the incident signal onto a detector; and
deriving, at the detector, the error signal based on a geometric beam shape of the propagated incident signal on the detector;
wherein the error signal has a local minimum and a local maximum,
wherein the local minimum and the local maximum delimit an interval of error signal values, and
wherein the conversion configuration configures the interval to comprise a zero-crossing of the error signal when the optical cavity is in a target state.
